(19) United States
(12) Patent Application Publication
(10) Pub. No.: US 2013/0043869 A1
(43) Pub. Date: Feb. 21, 2013

(54) DECONVOLUTION OF CHEMICAL MIXTURES WITH HIGH COMPLEXITY BY NMR CONSENSUS TRACE CLUSTERING

(71) Applicants: Rafael Brüschweiler, Tallahassee, FL (US); Kerem Bingol, Tallahassee, FL (US)

(72) Inventors: Rafael Brüschweiler, Tallahassee, FL (US); Kerem Bingol, Tallahassee, FL (US)

(73) Assignee: FLORIDA STATE UNIVERSITY RESEARCH FOUNDATION, INC., Tallahassee, FL (US)

(21) Appl. No.: 13/572,091

(22) Filed: Aug. 10, 2012

Related U.S. Application Data
(60) Provisional application No. 61/523,494, filed on Aug. 15, 2011.

(51) Int. Cl. G01R 33/465

(52) U.S. Cl. 324/309

(57) ABSTRACT

This disclosure provides new multidimensional-NMR approaches that are useful in the analysis of mixtures with high complexity at natural ¹³C abundance, including ones encountered in metabolomics. Common to all three approaches is the concept of the extraction of 1D consensus spectral traces or 2D consensus planes followed by clustering, which significantly improves the capability to identify mixture components affected by strong spectral overlap. The methods are demonstrated for covariance ¹H-¹H TOCSY and ¹³C-¹H HSQC-TOCSY spectra and triple-rank correlation spectra constructed from pairs of ¹³C-¹H HSQC and ¹³C-¹H HSQC-TOCSY spectra. All methods are demonstrated for a metabolite model mixture and then applied to an extract from E. coli cell lysate. This disclosure also provides a homonuclear ¹³C 2D NMR approach, namely CT-TOCSY, which is applied to a non-fractionated uniformly ¹³C-enriched lysate of E. coli cells to determine de novo the carbon backbone topologies that constitute their “topolome”.

### CROSS REFERENCE TO RELATED APPLICATIONS

This application claims the benefit of U.S. Provisional Application No. 61/523,494, filed Aug. 15, 2011, which is incorporated herein by reference in its entirety.

### STATEMENT REGARDING FEDERALLY SPONSORED RESEARCH

This invention was made with government support under National Institutes of Health Grant No. R01 GM 066041. The government may have certain rights in the invention.

### TECHNICAL FIELD OF THE INVENTION

This disclosure relates generally to the identification and quantification of analytes in solution in complex mixtures using nuclear magnetic resonance (NMR) techniques.

### BACKGROUND OF THE INVENTION

A characteristic feature of biological systems is their high level of chemical complexity. A multitude of metabolites serve diverse cellular functions, such as messengers, enzymatic substrates, energy source, molecular and structural building blocks, and the like. The metabolic characterization of biological samples either uses potentially elaborate chromatographic separation procedures prior to analysis or it applies nuclear magnetic resonance (NMR) or mass spectroscopic methods directly to the non-fractionated samples. The latter approach is commonly used for the identification of biomarkers by statistical analysis of 1D NMR spectra from different samples and for the identification of metabolites by databank screening. Many biological samples, however, contain a significant number of unknown metabolites that are not catalogued in databanks. Their systematic identification and structural characterization is therefore an important target.

Complex chemical systems are present in a wide range of natural and synthetic products, food and fuel samples, environmental systems and samples, and chemically monitoring such systems, including following reaction kinetics and biochemical studies such as metabolomics and metabonomics, focus on the identification of individual compounds in complex mixtures. Thus, improved analytical methods for all these intricate mixtures is an important objective, and NMR techniques can provide a range of powerful tools for complex analysis and a means for developing improved analytical methods.

In some magnetic resonance procedures, 1D and 2D NMR spectra of multiple samples are analyzed individually to identify spin systems by statistical correlation and difference mapping. Although more time-consuming than 1D NMR, the achievable gain in resolution makes 2D NMR an attractive method for detailed analysis of complex mixtures. Some methods examine single samples and identify individual compounds based on the characteristic translational diffusion constants or NMR relaxation rates of their peaks. Another strategy uses intramolecular magnetization transfer, especially via scalar J-couplings to identify individual spin systems that can be assigned to the various mixture components. In these latter experiments, for example, J-correlations between protons that are separated by typically no more than three covalent bonds can be established from a 2D ¹H-¹H COSY (Correlation Spectroscopy) spectrum. When combined with ¹³C-¹H HSQC (Heteronuclear Singular Quantum Correlation) information, these data can serve de novo chemical structure characterization of molecules in complex mixtures.

For sensitivity reasons, so far, a majority of applications has been based on 2D ¹H NMR experiments taking advantage of the high natural abundance of proton spins and their relatively large magnetic moment. For example, the strong conformation-dependence of vicinal ³J(¹H, ¹H)-couplings, however, can cause uneven magnetization transfer in TOCSY and COSY spectra, thereby impeding the assignment of cross-peaks to individual spin systems or entire molecules. Furthermore, the spectral information of protons may not be sufficient for the complete reconstruction of the carbon backbone of metabolites and their bonding topology, which is a prerequisite for structure determination. Thus, new and improved methods are still needed that allow the unambiguous identification of components in complex chemical mixtures, particularly those in biological systems but also in synthetic systems, that can combine the advantages of homo- and heteronuclear 2D NMR. Also by way of example, particularly useful would be methods that combine pairs of standard 2D FT spectra that share a common frequency dimension, that allows identification and quantification of individual components in complex chemical mixtures, without some of the current problems such as cross-peak overlaps leading to false peaks.

### SUMMARY OF THE INVENTION

Among other things, this disclosure addresses some of these issues associated with 2D and/or 3R spectral analysis, for example, this disclosure describes methods that have been developed to unambiguously identify individual components in complex chemical mixtures, particularly those in biological systems, but also for synthetic systems. In particular, this disclosure presents new methods for the deconvolution of mixtures from 2D and 3R NMR spectra, which are specifically geared toward application to highly complex mixtures, exemplified here by an E. coli cell lysate. This disclosure also presents a comprehensive approach for the characterization of the metabolic content of uniformly ¹³C-enriched cells based on homonuclear 2D ¹³C NMR, in which the large one-bond scalar couplings (¹J(¹³C,¹³C)>30 Hz) make the efficient transfer of spin magnetization during ¹³C-TOCSY mixing possible, and presented herein are methods to mitigate the increased cross-peak overlap resulting from the broad multiplet structures that also result from large ¹J(¹³C,¹³C)-couplings.

Correlation information of individual spin systems has been obtained from frequency-selective 1D TOCSY (Total Correlation Spectroscopy) or 2D TOCSY, in combination with clustering methods, such as DemixC (C stands for clustering). Disadvantage of ¹H-NMR based approaches is the common occurrence of relatively broad multiplets of ¹H peaks due to homonuclear ¹H-¹H J-couplings, which lead to increased peak overlaps, a feature that makes obtaining the desired correlation information more difficult and less reliable. Thus, DemixC methods were developed to overcome some of these limitations by identifying for each component characteristic traces that are essentially free of overlaps, therefore allowing identification and assignment with high confidence. These methods are disclosed in U.S. Pat. No. 7,835,872, which is incorporated herein by reference in its entirety. Specifically, these methods provide a new analytical tool for the deconvolution of the NMR spectrum of a mixture into individual components and spin systems. These methods do not require hyphenation and are based on covariance total correlation spectroscopy (TOCSY) spectra. Because experimental efficiency is desirable for high-throughput applications, TOCSY may be combined with covariance NMR, which produces high-resolution spectra largely independent of the number of increments along the indirect time domain t₁.

At natural ¹³C abundance, heteronuclear J-coupling-based ¹³C-¹H HSQC spectra display large chemical shift dispersions with very narrow lines along the proton-decoupled ¹³C-dimension ω₁, making cross-peak overlap relatively rare. While this favorable feature may offset the sensitivity loss compared to homonuclear spectra, HSQC-type spectra in contrast to TOCSY and COSY suffer from the lack of complete spin system information, as each cross-peak is independent of all others. On the other hand, the HSQC spectra of individual analytes represent useful fingerprints providing the number of C—H spin pairs of the molecule together with the ¹³C and ¹H chemical shifts, which reflect the nature of the chemical groups they belong to. Thus, 2D HSQC spectroscopy has found application in identifying and quantifying chemical components in complex mixtures.

Recently, the merging of HSQC with TOCSY in the form of the 3D ¹³C-¹H HSQC-TOCSY experiment combines many of the advantages of homo- and heteronuclear 2D NMR for unambiguous metabolite identification. However, relatively low sensitivity is still a limiting feature of this method. Moreover, to attain the desired high resolution along the indirect ¹³C dimension, protracted NMR measurement times are required. Various attempts to remedy this limitation have introduced their own unique problems. For example, recently we introduced the triple-rank (3R) correlation method, which combines pairs of standard 2D FT spectra that share a common frequency dimension. For example, from high-resolution 2D ¹³C-¹H HSQC and 2D ¹H-¹H TOCSY spectra sharing the proton dimension, a triple-rank correlation spectrum can be constructed with ultrahigh spectral resolution along all dimensions. Such a correlation spectrum spreads out 1D TOCSY traces of individual spin systems along the ¹³C dimension, according to the chemical shifts of the ¹³C spins directly attached to the protons. While in the absence of spectral overlap the triple-rank spectrum is equivalent to the corresponding experimental 3D FT spectrum, the occurrence of cross-peak overlaps leads to false peaks. To minimize such effects, spectral filtering methods, which identify mismatches between the first and second moments of cross-peak profiles, may be useful to suppress false correlations.

In some aspects, the present disclosure presents methods for the deconvolution of mixtures from 2D and 3R NMR spectra, which also are specifically geared toward application to highly complex mixtures. For example, this disclosure describes new and improved methods that allow the unambiguous identification of components in complex chemical mixtures, particularly those in biological systems. In some aspects, the new methods can combine the advantages of homo- and heteronuclear 2D NMR. For example, new methods are presented for merging of HSQC with TOCSY in the form of the 3D ¹³C-¹H HSQC-TOCSY experiments. In some aspects, the methods can combine pairs of standard 2D FT spectra that share a common frequency dimension, that allows identification and quantification of individual components in complex chemical mixtures, without some of the current problems such as cross-peak overlaps.

Embodiments and aspects of this disclosure include the following. The first approach extends the application range of the DemixC method, a method which requires that each component in the mixture has at least one resonance that is not affected by overlap. Because for highly complex mixtures this requirement becomes increasingly stringent, this first method is based on the more tolerant requirement that each component has at least one TOCSY cross-peak that is resolved. In this case, extraction of 1D TOCSY traces that correspond to individual spin systems is based on a consensus approach that compares for each covariance TOCSY cross-peak cross sections (traces) along ω₁ and ω₂ for common peaks followed by trace clustering.

In a second aspect, this first approach is adopted to ¹³C-¹H 2D HSQC-TOCSY spectra, taking advantage of the high resolution attainable along the indirect ¹³C dimension. A third approach is also disclosed that applies triple-rank (3R) correlation spectroscopy by combining 2D ¹³C-¹H HSQC with 2D ¹³C-¹H HSQC-TOCSY to construct a 3R HSQC-TOCSY spectrum. This third approach is used to extract pure 2D ¹³C-¹H HSQC spectra of the individual mixture components using a 2D version of the consensus algorithm described herein.

For example, in one aspect, the embodiments provided herein include a method for the deconvolution of an NMR spectrum of a chemical mixture, the method comprising the steps of:
obtaining a 2D ¹H-¹H TOCSY spectrum of a chemical mixture, the spectrum comprising an N₁×N₂ matrix T with elements (Tₖⱼ);
applying direct covariance processing to matrix T, with regularization, to determine the covariance matrix C with elements (Cₖⱼ), wherein C=(T^{T}·T)^{1/2}, comprising diagonal peaks and cross-peaks along the two frequency axes of C;
applying standard peak picking to identify the cross-peaks of matrix C, represented by (k,k′), wherein k and k′ denote the position of each cross-peak;
for each cross-peak entry (k,k′), determining a consensus trace q^{(kk′)} processing the k^{th} and k′^{th} rows according to qⱼ^{(kk′)}=min(Cₖⱼ, C_{k′j}), wherein index j goes over all N₂ columns;
quantitatively comparing each 1D ¹H consensus trace qⱼ^{(kk′)} with every other consensus trace qⱼ^{(mm′)} to determine a similarity measure between pairs of traces;
clustering the complete set of consensus traces q^{(kk′)} and identification of those traces corresponding to 1D ¹H spectra of individual spin systems; and
identifying unique sets of spin systems and compounds as corresponding traces of the covariance matrix to create a final set of TOCSY traces.
   With the final set of TOCSY traces in hand, the individual components of the chemical mixture can be identified and assigned, for example, by inspection and/or by screening of a spectral database.

Also by way of example, other embodiments that adopt this first approach to ¹³C-¹H 2D HSQC-TOCSY spectra and take advantage of the high resolution attainable along the indirect ¹³C dimension include deconvolution of an NMR spectrum of a chemical mixture, the method comprising the steps of:
obtaining a 2D ¹³C-¹H HSQC-TOCSY spectrum of a chemical mixture, the spectrum comprising an N₁×N₂ matrix T with elements (Tₖⱼ);
applying indirect covariance processing on the matrix T to determine the covariance matrix C with elements (Cₖⱼ), wherein C=(T·T^{T})^{1/2}, comprising cross-peaks along the two frequency axes of C;
applying standard peak picking to identify the cross-peaks of matrix C, represented by (k,k′), wherein k and k′ denote the position of each cross-peak;
for each cross-peak entry (k,k′), determining a consensus trace q^{(kk′)} by processing the k^{th} and k′^{th} rows according to qⱼ^{(kk′)}=min(Tₖⱼ,T_{k′j}), wherein index j goes over all N₂ columns;
quantitatively comparing each 1D ¹H consensus trace qⱼ^{(kk′)} with every other consensus trace qⱼ^{(mm′)} to determine a similarity measure between pairs of traces; and
carrying out the clustering of the complete set of consensus traces, identification of those traces corresponding to 1D ¹H spectra of individual spin systems, and identifying and assigning individual components of the chemical mixture from a final set of magnitude traces, wherein these steps can be carried out in a similar manner as described immediately above.

A further approach disclosed herein applies triple-rank (3R) correlation spectroscopy by combining 2D ¹³C-¹H HSQC with 2D ¹³C-¹H HSQC-TOCSY to construct a 3R HSQC-TOCSY spectrum. This third approach is used to extract pure 2D ¹³C-¹H HSQC spectra of the individual mixture components using a 2D version of the consensus algorithm described herein. In this aspect, the disclosure provides a method for the deconvolution of an NMR spectrum of a chemical mixture, the method comprising the steps of:
obtaining a 2D ¹³C-¹H HSQC spectrum of a chemical mixture, the spectrum comprising an N₁×N₂ matrix H with elements (Hₖᵢ), wherein matrix H has an average value of column i and an average value of row k;
obtaining a 2D ¹³C-¹H HSQC-TOCSY spectrum of a chemical mixture, the spectrum comprising an N₁×N₂ matrix T with elements (Tₖⱼ),
wherein in matrix H and matrix T, N₁ is the number of points along the indirect ¹³C dimension and N₂ is the number of points along the direct ¹H dimension;
constructing a triple rank spectrum R from the elements Hₖᵢ of H and Tₖⱼ of T, wherein Rₖᵢⱼ=HₖᵢTₖⱼ, wherein R corresponds to a collection of 2D ¹³C-¹H HSQC spectra with indices k, i for their ¹³C and ¹H dimensions, respectively, along the additional proton dimension j of the 2D ¹³C-¹H HSQC-TOCSY spectrum;
for each ¹H index pair (j,j′) of R, determining a HSQC consensus plane representing the element-by-element geometric averages according to Qₖᵢ^{(jj′)}=(Rₖᵢⱼ·R_{kij′})^{1/2}, wherein index i goes over all columns and index k goes over all rows;
quantitatively comparing each HSQC consensus plane Qₖᵢ^{(jj′)} with every other consensus plane Qₖᵢ^{(nn′)} via the inner product P_{jj′,nn′} to determine a similarity measure 1−P_{ji′,nn′} between pairs of planes;
clustering the complete set of consensus planes Qₖᵢ^{(jj′)} for the identification of those planes in R corresponding to unique 2D ¹³C-¹H HSQC spectra of individual spin systems; and
identifying unique sets of spin systems with N_{P} protons corresponding to N_{P} HSQC planes in the triple rank spectrum R.

Some aspects of the disclosed methods have been reported in, for example, Zhang and Brüschweiler Angew. Chem. Int. Ed. 2007, 46, 2639-2642) and Bingol, Zhang, Bruschweiler-Li, and Bruschweiler, J. Am. Chem. Soc. 2012, 134, 9006-9011, which are hereby is incorporated by reference in their entireties.

Another aspect of this disclosure provides a comprehensive approach for the characterization of the metabolic content of uniformly ¹³C-enriched cells, or any ¹³C-containing sample or biological or synthetic origin, based on homonuclear 2D ¹³C NMR. The large one-bond scalar couplings (¹J(¹³C,¹³C)>30 Hz) make the efficient transfer of spin magnetization during ¹³C-TOCSY mixing possible. On the other hand, the same ¹J(¹³C,¹³C)-couplings lead to broad multiplet structures resulting in increased cross-peak overlap, and these can be mitigated along the indirect ω₁ dimension by ¹³C-¹³C constant-time (CT) TOCSY spectroscopy. In this aspect, there is disclosed a method for the deconvolution of an NMR spectrum of a chemical mixture comprising the steps of:
obtaining a 2D ¹³C-¹³C CT (constant time)-TOCSY spectrum of a chemical mixture, the spectrum comprising an N₁×N₂ matrix T with elements (Tₖⱼ);
applying standard peak picking to the 2D ¹³C-¹³C CT-TOCSY spectrum to identify the cross-peaks of matrix T, represented by (k,k′), wherein k and k′ denote the position of each cross-peak along two frequency axes;
for each cross-peak pair (k,k′) and (l,l′) placed symmetrically with respect to the diagonal, extracting the k^{th} and l^{th} row from T to determine a consensus trace qⱼ^{(kl)} according to qⱼ^{(kl)}=min(Tₖⱼ,Tₗⱼ), wherein index/=1, . . . , N₂;
quantitatively comparing each 1D ¹³C consensus trace q^{(kl)} with every other consensus trace q^{(mn)} to determine a similarity measure 1−P_{kl,mn} between pairs of traces; and
clustering the complete set of consensus traces q^{(kl)} and identification of those traces that represent 1D ¹³C spectra of individual spin systems.

These and other aspects and embodiments of the disclosure are presented herein.

### BRIEF DESCRIPTION OF THE FIGURES

FIG. 1. (A) Dendrogram of cluster analysis based on similarity of pairs of ¹H traces calculated by 2D DeCoDeC approach applied to (B) covariance ¹H-¹H TOCSY spectrum of cell lysate. (C,D) Representative examples of NMR 1D spectra constructed by 2D DeCoDeC from 2D TOCSY of Panel B. From top to bottom: (C) valine, isoleucine, glutamine, lysine; (D) leucine, proline, cystine, ribose ring of adenosine.

FIG. 2. (A) Dendrogram of cluster analysis based on similarity of the pairs of ¹H traces calculated by 2D DeCoDeC approach applied to (B) 2D ¹³C-¹H HSQC-TOCSY spectrum of cell lysate. (C,D) Representative examples of 1D NMR spectra constructed by 2D DeCoDeC from 2D HSQC-TOCSY of Panel B from top to bottom. From top to bottom: (C) valine, isoleucine, glutamine, lysine; (D) leucine, proline, cystine, ribose ring of adenosine.

FIG. 3. (A) Dendrogram of cluster analysis based on similarity of pairs of HSQC planes from 3R spectrum constructed from a 2D ¹³C-¹H HSQC (Panel B) and a 2D ¹³C-¹H HSQC-TOCSY spectrum of cell lysate. (C) Comparison of 3R HSQC plane of leucine with (D) corresponding HSQC in the BMRB. (E) Comparison of 3R HSQC plane of ribose ring of cytidine with (F) corresponding HSQC spectrum in the BMRB.

FIG. 4. (A) Dendrogram of cluster analysis based on similarity of the pairs of ¹H traces calculated by 2D DeCoDeC approach applied to (B) covariance ¹H-¹H TOCSY spectrum of model mixture. (C,D) Representative examples of NMR 1D spectra constructed by 2D DeCoDeC from 2D TOCSY of Panel B. From top to bottom: (C) ornithine, lysine, arginine, glutamate; (D) alanine, isoleucine, shikimate, carnitine. Labels a,b,c,d in (B) denote traces of 2D TOCSY whose consensus traces yield the lysine spectrum (a,b) and the carnitine spectrum (c,d) as indicated in Panels A, C, D. The tilted arrows in Panel B indicate the 2 TOCSY cross-peaks from which traces (a,b) and (c,d) were derived.

FIG. 5. (A) Dendrogram of cluster analysis based on similarity of the pairs of ¹H traces calculated by 2D DeCoDeC approach applied to (B) 2D ¹³C-¹H HSQC-TOCSY spectrum of model mixture. (C,D) Representative examples of 1D NMR spectra constructed by 2D DeCoDeC from 2D HSQC-TOCSY of Panel B. From top to bottom: (C) ornithine, lysine, arginine, glutamate; (D) alanine, isoleucine, shikimate, carnitine.

FIG. 6. (A) Dendrogram of cluster analysis based on similarity of pairs of HSQC planes from 3R spectrum constructed from a 2D ¹³C-¹H HSQC (Panel B) and a 2D ¹³C-¹H HSQC-TOCSY spectrum (Panel B of FIG. 5) of the model mixture. (C) Comparison of 3R HSQC plane of lysine with (D) corresponding HSQC spectrum in the BMRB. (E) Comparison of 3R HSQC plane of isoleucine with (F) the corresponding 2D HSQC reference spectrum of isoleucine taken from the BMRB.

FIG. 7. 1D NMR spectra taken from the BMRB of the following compounds (from top to bottom): (A) ornithine, lysine, arginine, glutamate; (B) alanine, isoleucine, shikimate, carnitine. Shaded areas correspond to the 1D spectral regions shown in FIGS. 4 and 5.

FIG. 8. 1D NMR spectra of the following compounds in the BMRB (from top to bottom): (A) valine, isoleucine, glutamine, lysine; (B) leucine, proline, cystine, ribose ring of adenosine. Shaded areas correspond to the 1D spectral regions shown in FIGS. 1 and 2 of the main text.

FIG. 9. Full 1D spectrum of shikimate calculated by 2D DeCoDeC method applied to (A) covariance ¹H-¹H TOCSY spectrum and (C) 2D ¹³C-¹H 2D HSQC-TOCSY spectrum of model mixture. Full 1D spectrum of ribose of adenosine calculated by 2D DeCoDeC method applied to (B) covariance ¹H-¹H TOCSY spectrum and (D) 2D ¹³C-¹H HSQC-TOCSY spectrum of cell lysate.

FIG. 10. Application of DemixC method to covariance TOCSY spectrum of model mixture. Successfully identified compounds based on their importance index numbers are (9,4) shikimate, (8) arginine, (7) ornithine, (6) alanine, (5) isoleucine, (2) carnitine. Because of the presence of overlaps in the cross sections of lysine and low concentration of glutamate, DemixC did not identify the lysine and glutamate traces.

FIG. 11. Performance of DemixC on cell lysate covariance TOCSY spectrum. Successfully identified compounds based on their importance numbers are (8) glutamine, (6) valine, (2) leucine with one extra false peak, (1) unknown compound.

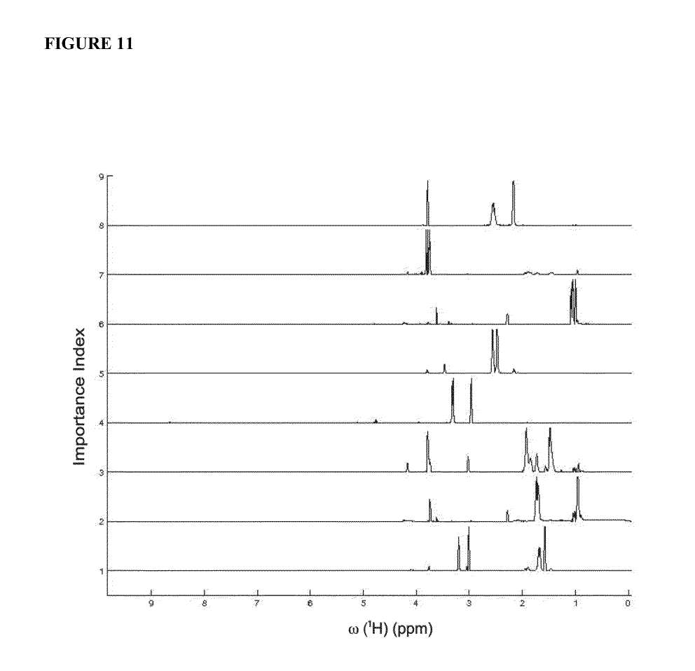

FIG. 12. (A) Full 1D ¹H NMR spectrum of the cell lysate sample acquired with 16 scans and water presaturation. The amplified baseline noise is given in the top-left corner. (B) Selected down-field region of (A), which is 45-fold amplified. The experimental conditions are the same as for the other NMR spectra.

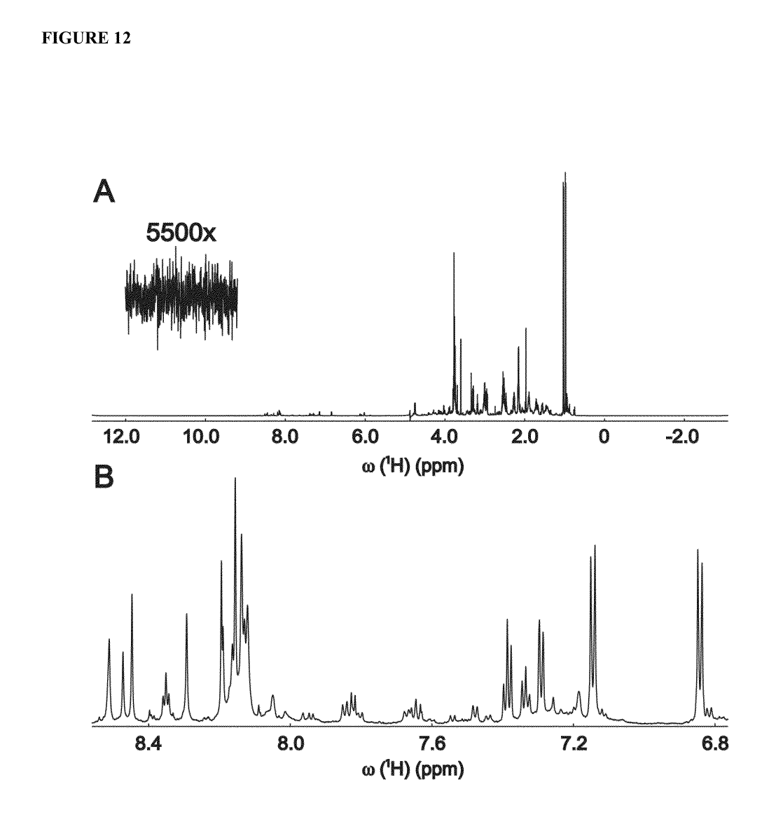

FIG. 13. Flow chart of the 2D CT-TOCSY deconvolution protocol as used in embodiments of this work.

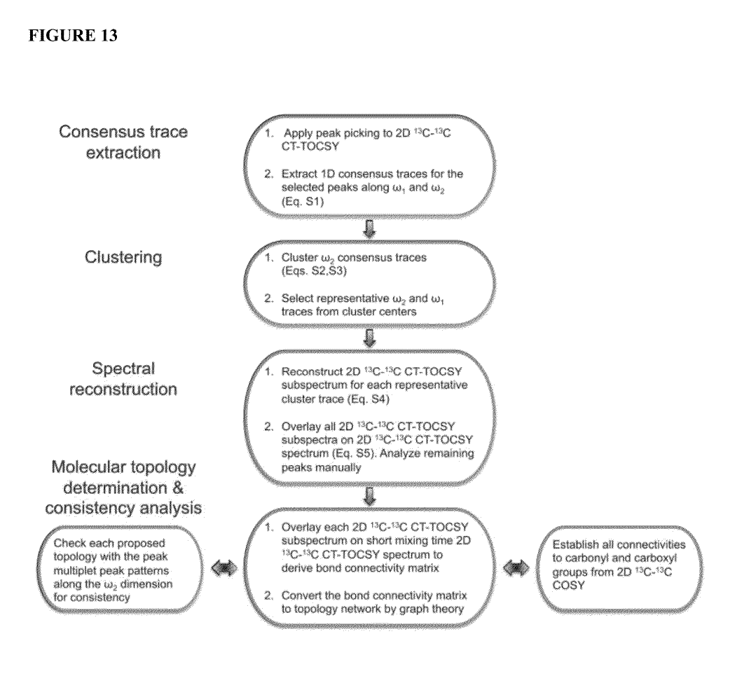

FIG. 14. Illustrated are selected regions of (A) ¹³C-¹³C₂D TOCSY and (B) ¹³C-¹³C 2D constant-time (CT) TOCSY of uniformly ¹³C-labeled E. coli cell lysate. The large resolution improvement along ω₁ in the CT-TOCSY experiment enables the extraction of unique traces for their assignment to individual metabolites.

FIG. 15. (A) Dendrogram representation of the consensus trace clustering result of 2D CT-TOCSY traces (cross sections) along ω₂ of ¹³C-labeled cell lysate. The x-axis corresponds to the consensus trace indices. (B) 98 Semi-automatically determined ¹³C NMR cluster center traces that represent the clusters of Panel A.

FIG. 16. ¹³C-¹³C₂D CT-TOCSY spectrum (A, red) in comparison with spectrum S (B, black), which was back-calculated from the cluster center traces of FIG. 2B. Panels C and D show the zoomed regions (gray boxes) of the spectra of Panels A and B, respectively, resolving details of the multiplet patterns.

FIG. 17. Backbone carbon topologies of (A) coenzyme A, (B) ribose of uridine, (C) β-galactose, (D) leucine from ¹³C-¹³C cross-peak connectivities of 2D CT-TOCSY at short mixing time (τₘ=4.7 ms) and from ¹³C-multiplet patterns along the ω₂ dimension in CT-TOCSY.

FIG. 18. Backbone carbon topolome of E. coli. (A) Display of the backbone carbon topologies of the 112 spin systems of E. coli identified in this study. (B) List of the different topologies identified together with their occurrences (Occ.). Compounds with specific names matched BMRB database compounds, whereas compounds referred to as “others”, “amino-acid like”, and “saccharides” were not contained in the database.

FIG. 19. Entire 2D ¹³C-¹³C CT-TOCSY spectrum of uniformly ¹³C-labeled cell extract from E. Coli BL21(DE3) cells.

FIG. 20. Entire ¹³C-¹³C COSY spectrum of uniformly ¹³C-labeled cell extract from E. Coli BL21(DE3) cells. The boxed areas contain cross-peaks to carbonyl and carboxyl carbons complementing the information obtained from the ¹³C-¹³C TOCSY spectrum of FIG. 19.

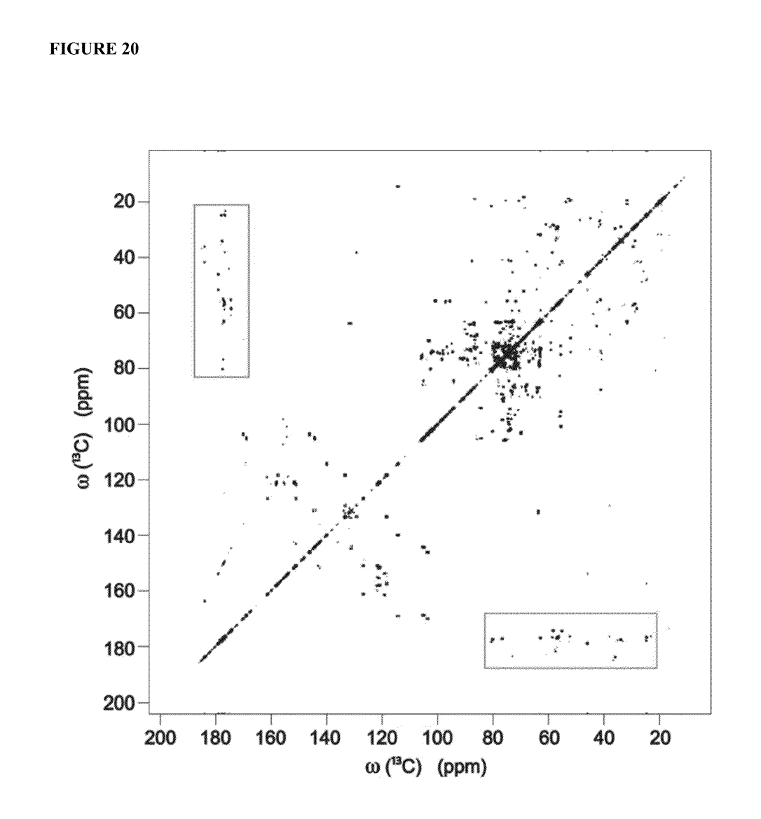

FIG. 21. Back-calculated spectrum S^{(cc)} (blue, Eq. (13)) back-calculated from selected ω₁ consensus traces superimposed on the 2D CT-TOCSY (red). The dashed lines connect ¹³C-¹³C cross-peaks from the ribose of adenosine.

FIG. 22. Back-calculated spectrum S^{(cc)} (blue, Eq. (13)) back-calculated from selected ω₁ consensus traces superimposed on the 2D CT-TOCSY (red). The dashed lines connect ¹³C-¹³C cross-peaks from leucine.

FIG. 23. Simulated magnetization transfer between ¹³C spins in a linear chain consisting of N=10 spins under isotropic TOCSY mixing. The simulation included only the dominant next-neighbor scalar J-couplings (¹J(¹³C,¹³C)=35 Hz). Starting on the first spin, the propagation of single spin magnetization through the spin system is depicted as a function of the TOCSY mixing time where the spins are sequentially numbered as indicated in the figure. At 47 ms the transfer efficiency to all spins is reasonably high. For N>12 spins, a longer TOCSY mixing time is required as would be the case, for example, for long lipid chains and cholesterol. From a practical perspective, a signature for incomplete magnetization transfer is the presence of TOCSY traces that have high similarity for only a subset of resonances. However, at 47 ms mixing time such behavior was not detected for the compounds of the E. coli cell lysate.

### DETAILED DESCRIPTION OF THE PREFERRED EMBODIMENTS

In this disclosure, new strategies for the deconvolution of mixtures from 2D and 3R NMR spectra are presented, which are specifically geared toward application to highly complex mixtures. In one aspect, the highly complex mixtures are exemplified herein by an E. coli cell lysate.

In a further aspect, the metabolome of a cell is characterized by a novel homonuclear ¹³C 2D NMR approach applied to a non-fractionated uniformly ¹³C-enriched lysate of E. coli cells and their carbon backbone topologies that constitute the “topolome” are determined de novo. A protocol is disclosed, which first identifies traces in a constant-time ¹³C-¹³C TOCSY NMR spectrum that are unique for individual mixture components and then assembles for each trace the corresponding carbon-bond topology network by consensus clustering. Examples are provided by which this method leads to the determination of 112 topologies of unique metabolites from a single sample.

### I. Natural ¹³C Abundance Methods

### Extraction of 1D Consensus Spectral Traces or 2D Consensus Planes Followed by Clustering

Computational Methods

A first approach for the deconvolution of mixtures extends the application range of the DemixC method (see Zhang and Brüschweiler Angew. Chem. Int. Ed. 2007, 46, 2639-2642), a method which requires that each component in the mixture has at least one resonance that is not affected by overlap. For highly complex mixtures this requirement becomes increasingly stringent, but the present disclosure provides a method that allows the more tolerant requirement that each component has at least one TOCSY cross-peak that is resolved. Extraction of 1D TOCSY traces that correspond to individual spin systems is based on a consensus approach that compares for each covariance TOCSY cross-peak cross sections (traces) along ω₁ and ω₂ for common peaks followed by trace clustering. This first approach is subsequently adopted to develop a second approach to ¹³C-¹H 2D HSQC-TOCSY spectra, taking advantage of the high resolution attainable along the indirect ¹³C dimension. A third approach is disclosed that applies triple-rank (3R) correlation spectroscopy by combining 2D ¹³C-¹H HSQC with 2D ¹³C-¹H HSQC-TOCSY in order to construct a 3R HSQC-TOCSY spectrum. This approach is used to extract pure 2D ¹³C-¹H HSQC spectra of the individual mixture components using a 2D version of the consensus algorithm described herein.

Consensus Peak Pattern Inferencing and Clustering.

Deconvolution of a 2D ¹H-¹H TOCSY or a 2D ¹³C-¹H HSQC-TOCSY spectrum, represented by a N₁×N₂ matrices T, of a complex mixture is performed as follows. We first applied direct covariance processing to T, C=(T^{T}·T)^{1/2} with regularization, in the case of TOCSY and indirect covariance processing, C=(T·T^{T})^{1/2}, in the case of HSQC-TOCSY. Peak picking of the cross-peaks of matrix C yields a list (k,k′) where k and k′ denote the position of a certain cross-peak along the two frequency axes. Next, for each cross-peak entry (k,k′) the consensus trace q^{(kk′)} is determined as follows. In the case of covariance TOCSY C, the k^{th} row and k′^{th} row are processed as

qⱼ^{(kk′)}=min(Cₖⱼ,C_{k′,j}) (1a)

whereas in the case of HSQC-TOCSY T

qⱼ^{(kk′)}=min(Tₖⱼ,T_{k′j}) (1b)

where index j goes over all N₂ columns. The complete set of consensus traces q^{(kk′)} is subsequently subjected to clustering for the identification of those traces that represent 1D ¹H spectra of individual spin systems. For this purpose, 1D ¹H consensus traces of Eqs. (1a,b) are quantitatively compared to each other via the inner product

$${P}_{{kk}^{′} , {mm}^{′}} = {\sum }_{j = 1}^{{N}_{2}} {q}_{j}^{( {kk}^{′} )} {q}_{j}^{( {mm}^{′} )} / ( ‖ {q}^{( {kk}^{′} )} ‖ \cdot ‖ {q}^{( {mm}^{′} )} ‖ ) \qquad ( 2 )$$

where the L2-norm of a consensus trace is given by

$$‖ {q}^{( {kk}^{′} )} ‖ = {[ {\sum }_{j = 1}^{{N}_{2}} {( {q}_{j}^{{kk}^{′}} )}^{2} ]}^{1 / 2} \qquad ( 3 )$$

A similarity measure between pairs of traces is then given by 1−P_{kk′,mm′}, which permits clustering, for example, using the agglomerative hierarchical cluster algorithm as implemented in the subroutine ‘linkage’ in the MATLAB® software package. The clustering result can be displayed as a dendrogram. We refer to this approach as Demixing by Consensus Deconvolution and Clustering or DeCoDeC.

Consensus Plane Inferencing and Clustering of Triple-Rank Correlation Spectrum.

A triple-rank spectrum R is constructed from a 2D ¹³C-¹H HSQC spectrum, represented by the N₁×N₂ matrix H, and a 2D ¹³C-¹H HSQC-TOCSY spectrum, represented by the N₁×N₂ matrix T, where N₂ is the number of points along the direct ¹H dimension and N₁ is the number of points along the indirect ¹³C dimension

Rₖᵢⱼ=HₖᵢTₖⱼ (4)

R can be considered as a collection of 2D ¹³C-¹H HSQC spectra (with indices k, i for their ¹³C and ¹H dimensions, respectively) along the additional proton dimension j of the 2D ¹³C-¹H HSQC-TOCSY spectrum. A detailed description of consensus plane extraction and clustering, referred to as 3R DeCoDeC, is provided in the Examples section, and general information can be found at Bingol and Brüschweiler, Anal. Chem. 2011, 1, 83, 7412-7417.

Experimental Details.

An extract from E. coli BL21(DE3) strain prepared as described in the Examples section. A model mixture was prepared in D₂O solution with 8 components where carnitine, alanine, isoleucine, ornithine, arginine, lysine, and shikimate are 10 mM each and glutamate is 1 mM (to introduce a 10-fold dynamic range). 2D ¹H-¹H TOCSY, 2D ¹³C-¹H HSQC, and 2D ¹³C-¹H HSQC-TOCSY data sets were collected for both samples as described in the Examples section herein.

Results of New Natural ^{B}C Abundance Methods

The cell lysate results are discussed first, followed by the results of the model mixture. The figures of the model mixture, which provide a detailed illustration of the methods introduced in this disclosure, are described in the Examples section.

Analysis of E. coli BL21(DE3) Cell Extract.

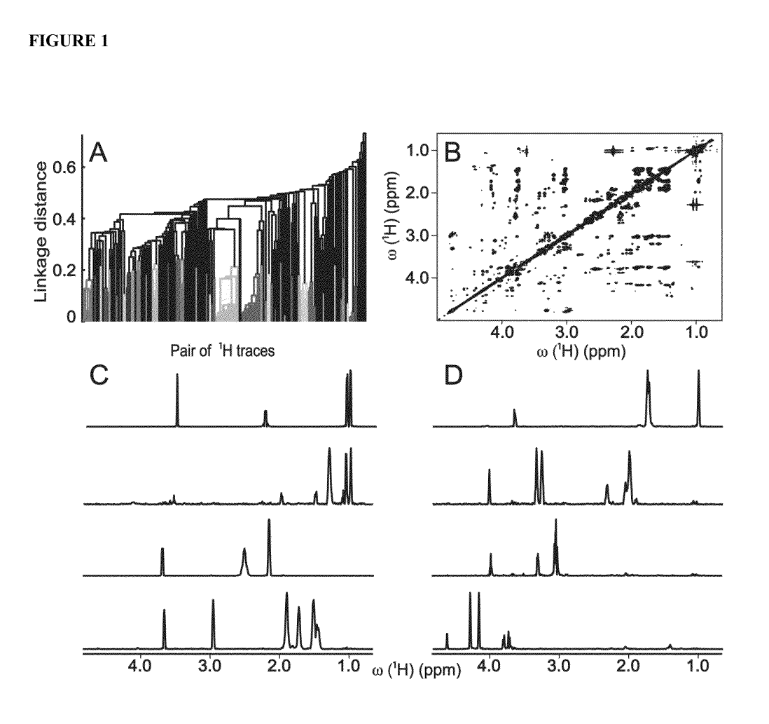

As a real-life application, the DeCoDeC methods were applied to an E. coli cell lysate eluted from a solid phase extraction cation-exchange column to partially remove saccharides and saccharide-containing compounds. These compounds would result in severe spectral congestion between 3 and 4 ppm in the ¹H dimension and 70 and 80 ppm in the ¹³C dimension. FIG. 1B displays the covariance processed 2D ¹H-¹H TOCSY spectrum of the cell lysate sample. Individual 1D spectra of valine, isoleucine, glutamine, lysine, leucine, proline, cystine, and ribose of adenosine are obtained by DeCoDeC as shown in FIG. 1C,D.

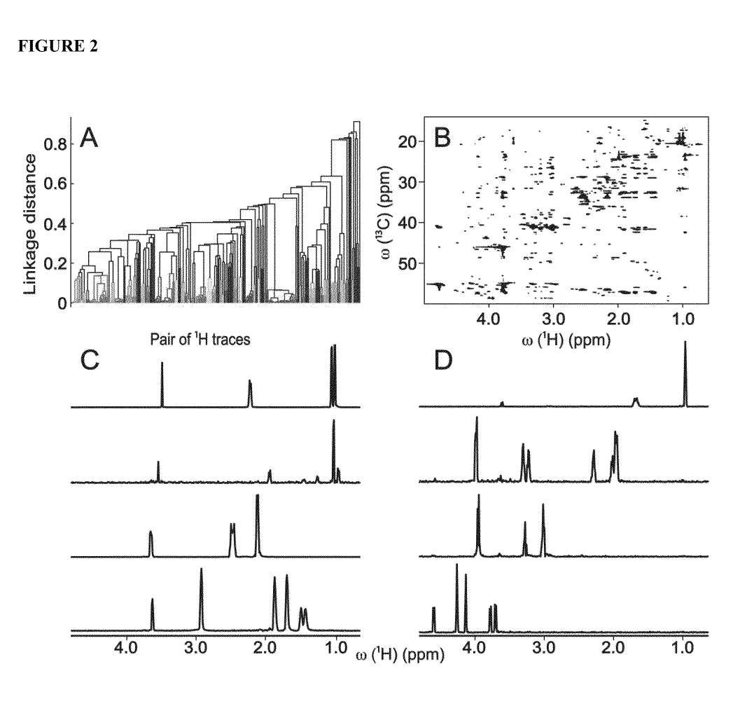

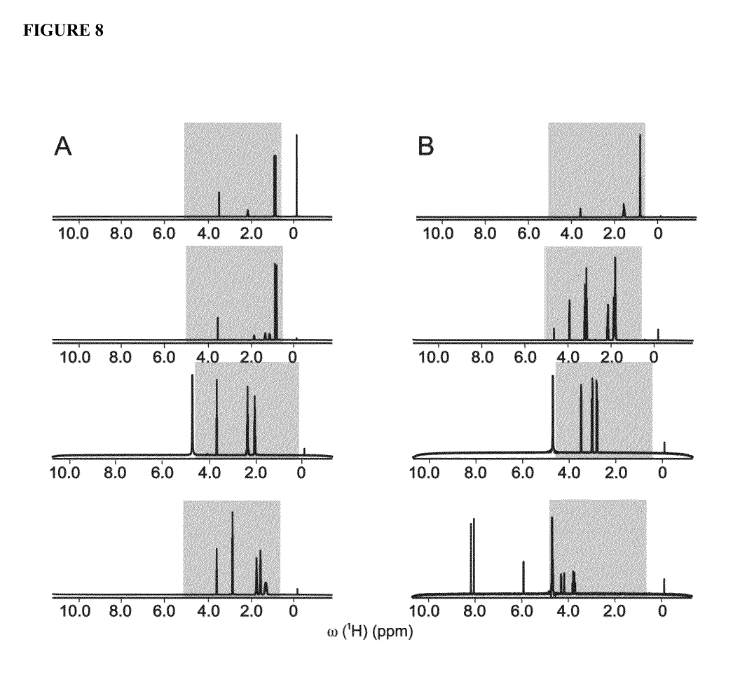

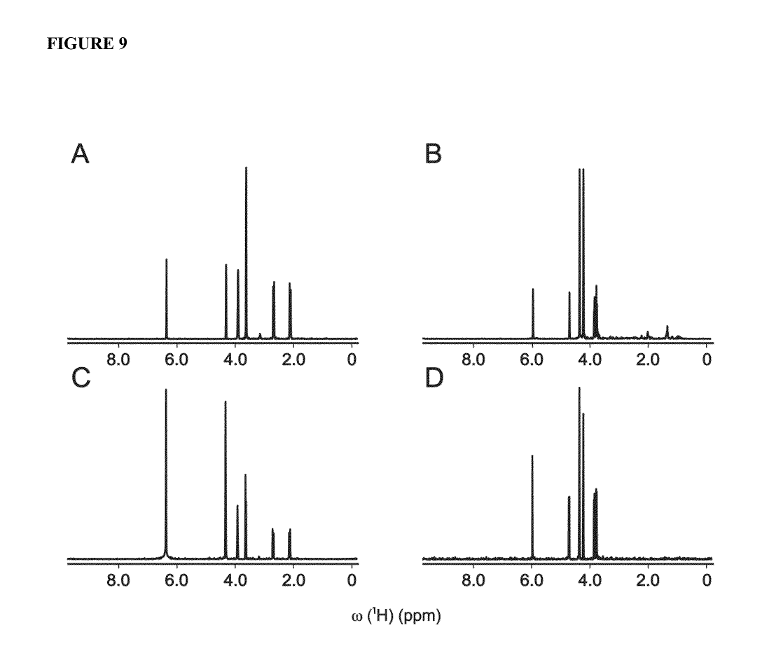

The deconvolution performance of DeCoDeC for the cell lysate based on the 2D ¹³C-¹H HSQC-TOCSY spectrum can be assessed from FIG. 2. Overall, there are no missing peaks in any of the spectra in FIGS. 1C,D and 2C,D, except for adenosine whose 1D ¹H spectrum in the BMRB has two additional peaks, which are not obtained by DeCoDeC, as these peaks are part of the nucleic acid and not of the ribose ring of adenosine. Since there is no detectable magnetization transfer between these molecular parts during TOCSY mixing, the proton signals coming from ribose protons and nucleic acid protons cannot be seen in the same 1D ¹H DeCoDeC trace. The ribose ring of adenosine shows one extra peak in the spectral regions of FIGS. 1 and 2 (for the full 1D ¹H spectra of ribose ring obtained by DeCoDeC see FIG. 9B,D). For a detailed comparison, 1D ¹H reference spectra taken from the BMRB of 8 compounds of the cell lysate are given in FIG. 8.

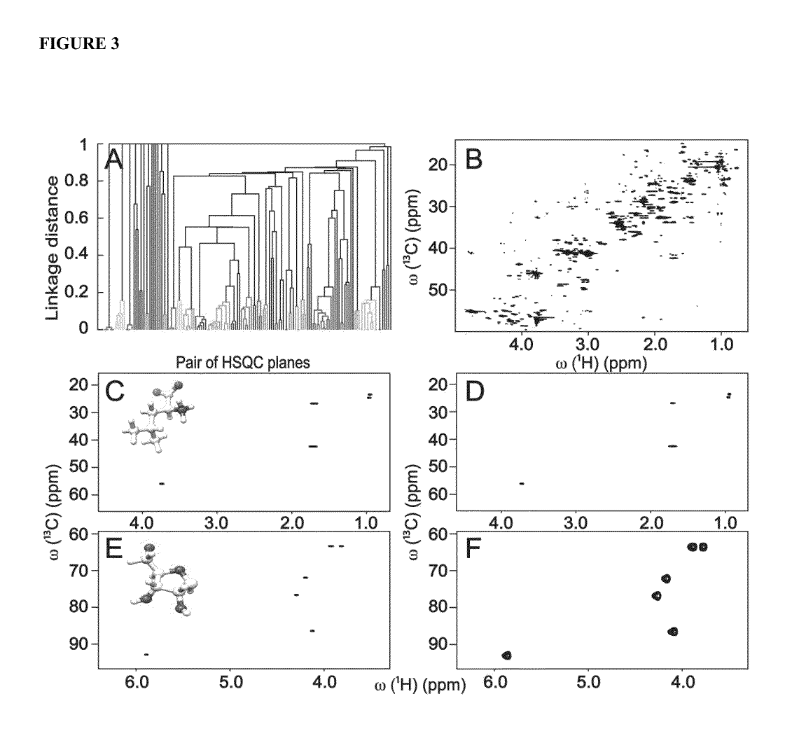

The result of the triple-rank approach for the cell lysate is illustrated in FIG. 3. Representative HSQC spectra for the following compounds are taken from the BMRB or HMDB databases: cystine, valine, isoleucine, leucine, proline, glutamine, lysine, glutathione, cytosine, and 4 ribose rings corresponding to different nucleic acid forms. The 2D ¹H-¹H TOCSY spectrum is used to confirm the identified and unidentified compounds in the cell lysate. Leucine and the ribose ring of cytidine are depicted as examples in FIG. 3C,E. Six HSQC planes, which could not be identified either in the BMRB or the HMDB database, were confirmed by ¹H-¹H TOCSY. Thus, the unidentified compounds are either not available in these databases or they belong to isolated spin systems of larger metabolites. Therefore, HSQC spectra extracted by 3R DeCoDeC only reflect a portion of these molecules.

Analysis of Model Mixture.

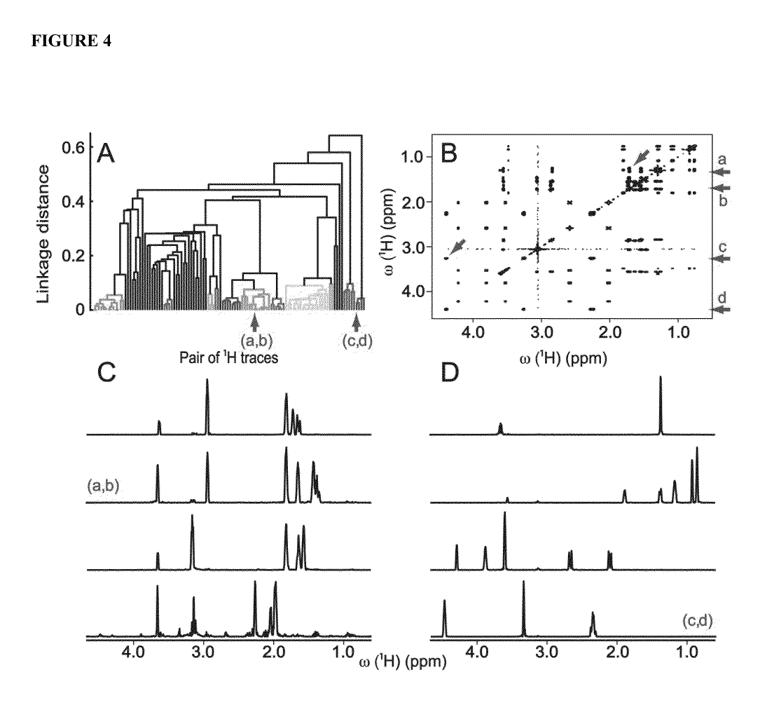

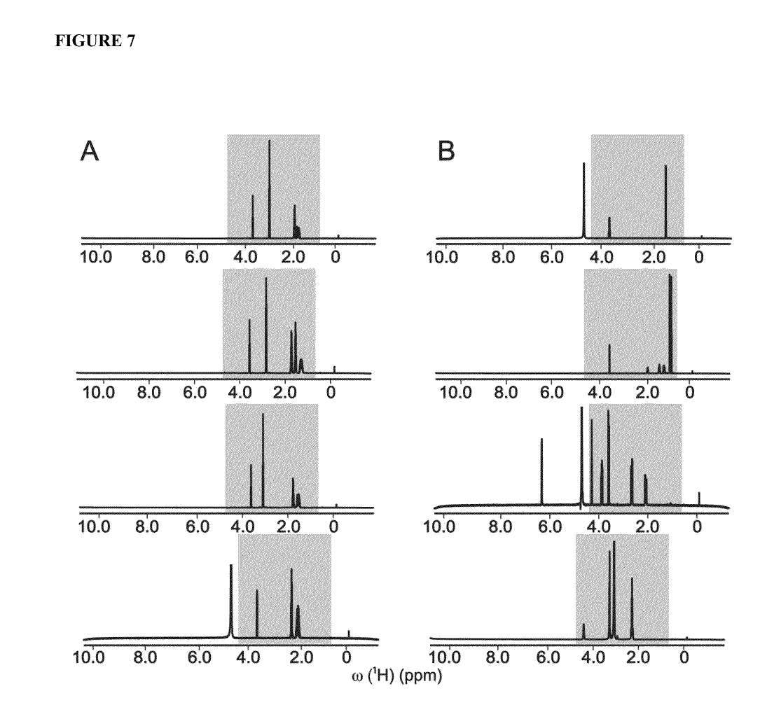

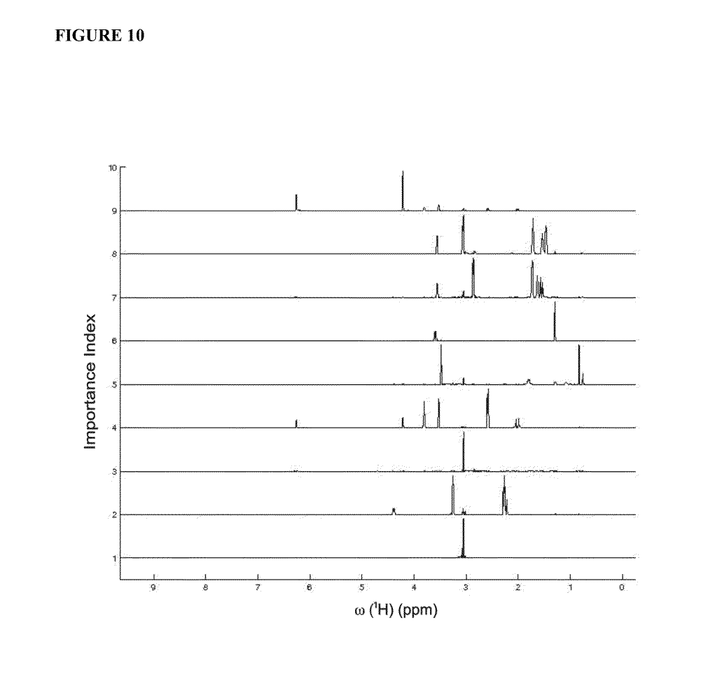

FIG. 4 illustrates the performance of the DeCoDeC approach on the 8-compound model mixture based on a single covariance processed 2D ¹H-¹H TOCSY spectrum. The spectrum exhibits several regions with spectral congestions due to similar chemical structures of arginine, lysine, and ornithine giving rise to peak overlaps across the spectrum. In addition, alanine, isoleucine, and lysine have overlapping peaks around 1.3 ppm. Application of the DeCoDeC procedure results in remarkably clean, overlap free 1D spectra for each compound in this mixture. Carnitine and lysine are chosen here to illustrate the DeCoDeC algorithm; see FIG. 4. Cross-peak picking generates a peak list with pairs of indices that define the chemical shifts of resonances that potentially belong to the same compound. Two cross-peaks (a,b) and (c,d) are chosen with the corresponding traces a,b,c,d indicated by arrows in Panel 4B. In the case of carnitine, the 2 traces c and d are not affected by overlaps, and DeCoDeC produces their consensus trace (c,d) as a clean 1D spectrum of carnitine (for comparison, a 1D reference spectrum of carnitine taken from the BMRB is displayed in FIG. 7). Lysine is more challenging, since trace (a) overlaps with alanine and isoleucine and trace (b) overlaps with ornithine and arginine. Nonetheless, DeCoDeC produces a consensus 1D trace (a,b) with peaks that solely belong to lysine as shown in FIG. 4C. The dendrogram of FIG. 4A shows that partitioning of the consensus traces into clusters is robust allowing the selection of representative cluster traces as 1D spectra. For comparison, the DemixC method applied to the same TOCSY spectrum via COLMAR (see Robinette et al. Anal. Chem. 2008, 80, 3606-3611 and Zhang et al. Magn. Reson. Chem. 2009, 47, S118-122) correctly captures the 1D spectra of 6 out of 8 compounds (see FIG. 10).

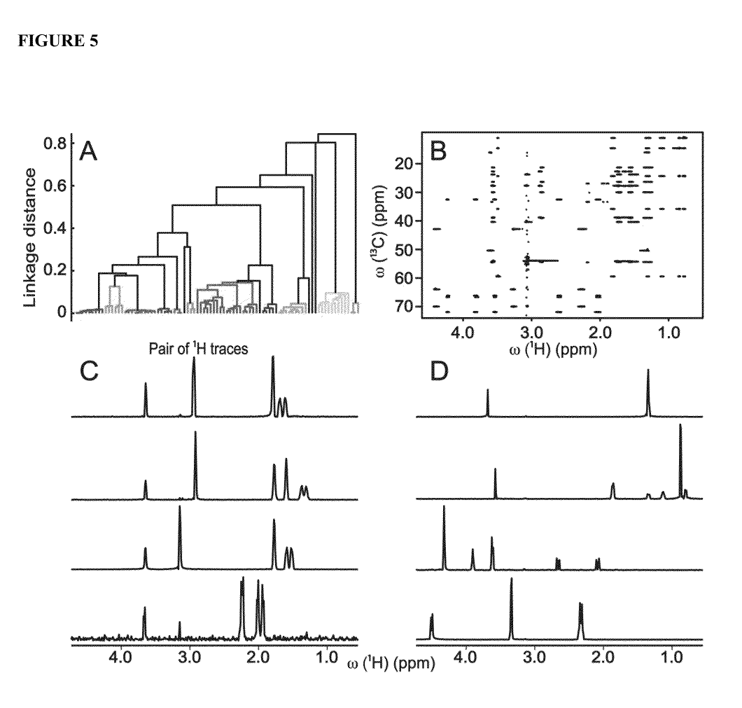

DeCoDeC can be applied in a similar manner for the analysis of the 2D ¹³C-¹H HSQC-TOCSY spectrum of the model mixture (FIG. 5). Because the spectrum exhibits sharp peaks and a large chemical shift dispersion along the ¹³C dimension, DeCoDeC performs with 100% accuracy with the consensus traces having even slightly better appearance (FIG. 5C,D) than in the case of 2D ¹H-¹H TOCSY.

Overall, there are no missing peaks in any of the DeCoDeC spectra in FIGS. 4C,D and 5C,D except for the (CH₃)₃ peak of carnitine (because it is not J-coupled to the rest of the molecule and hence does not exchange magnetization with other resonances during TOCSY mixing). Shikimate has one extra peak outside the spectral regions shown in FIGS. 4 and 5. For the full 1D ¹H spectra of shikimate obtained by DeCoDeC see FIGS. 9A,C.

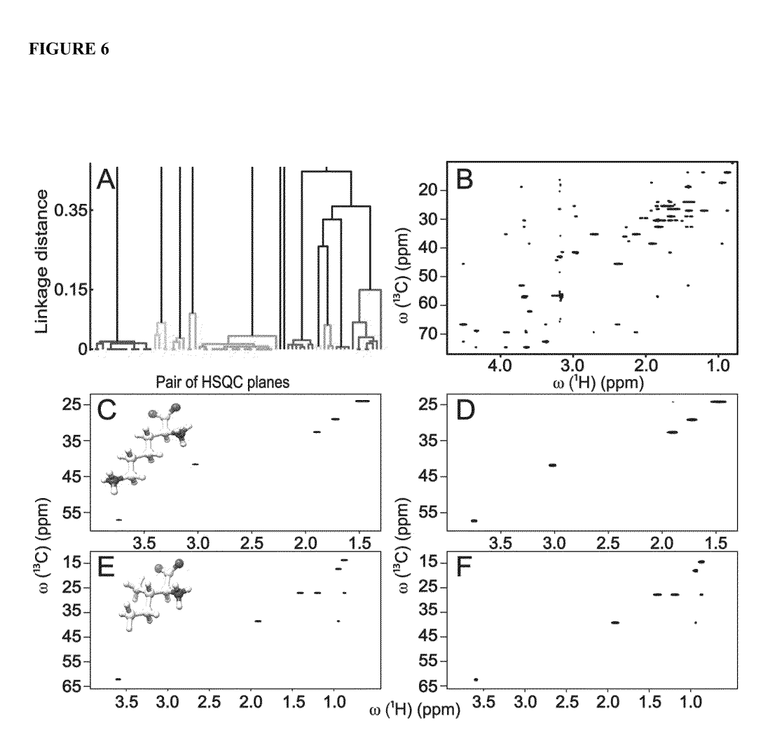

Application of 3R DeCoDeC to the same model mixture combines the 2D ¹³C-¹H HSQC spectrum of FIG. 6B with the 2D ¹³C-¹H HSQC-TOCSY spectrum of FIG. 5B to extract 2D ¹³C-¹H HSQC spectra of the individual compounds using Eq. (4). The representative HSQC spectrum for every compound is validated with the corresponding HSQC spectrum in the BMRB database. For the model mixture, the HSQC spectra of all 8 components are successfully extracted, which is illustrated for lysine and isoleucine in FIG. 6.

The dendrograms in FIGS. 4A, 5A and 6A illustrate the clustering results for the model mixture by applying DeCoDeC to the 2D ¹H-¹H TOCSY spectrum, DeCoDeC to the 2D ¹³C-¹H HSQC-TOCSY spectrum, and 3R DeCoDeC to the 3R spectrum constructed from the 2D ¹³C-¹H HSQC and 2D ¹³C-¹H HSQC-TOCSY spectral pair, respectively. In FIG. 4A, the locations of selected lysine (a,b) and carnitine (c,d) traces are labeled by arrows illustrating the DeCoDeC approach. The dendrogram is useful for visual inspection and validation of the clustering result and for selecting or verifying a suitable representative trace for each cluster.

Discussion of 2D DeCoDeC and 3R DeCoDeC Methods.

In one aspect, existing deconvolution approaches based on J-coupling mediated magnetization transfer generally can be divided into two groups. The first group focuses on matching the cross-peaks of a HSQC-type spectrum of the mixture with the cross-peaks of individual compounds compiled in a database. See, for example: Lewis et al. Anal. Chem. 2007, 79, 9385-9390; Cui et al. Nat. Biotechnol. 2008, 26, 162-164; and Chikayama et al. J. Anal. Chem. 2010, 82, 1653-1658. Optionally, the candidate compounds obtained from the database can be confirmed by using higher-dimensional experiments, such as 3D HCCH-COSY (see, for example, Sekiyama et al. J. Anal. Chem. 2011, 83, 719-726) by taking advantage of the higher resolution along the additional ¹³C dimension and the ¹H-¹H connectivity information. One disadvantage of this approach is that the compounds that can be extracted are limited to the ones stored in the databases, thereby preventing the discovery of novel and potentially useful compounds.

The second group of methods directly focuses on the connectivity information in 2D experiments, often from ¹H-¹H TOCSY (see, for example, Zhang and Brüschweiler Angew. Chem. Int. Ed. 2007, 46, 2639-2642.) Since chemical shift dispersion in the proton dimension may not be sufficient for the analysis of very complex mixtures, we have discovered that depending upon the cross-peak density in the TOCSY spectrum, TOCSY can be substituted by the 2D HSQC-TOCSY (see, for example, Zhang et al. Anal. Chem. 2008, 80, 7549-7553) experiment to make use of the chemical shift dispersion along the ¹³C dimension with narrow ¹³C line widths, which tends to be less prone to overlap. Both types of spectra then can be subjected to automated analysis based on an algorithm that searches for the ‘clean’ 1D cross sections in 2D spectrum to represent 1D spectra of individual compounds. Depending on the NMR properties of the components, this strategy generally works well for mixtures of moderate complexity. However, in mixtures of higher complexity, such as a crude cell extract, the cross-peak overlap problem can become so severe that no single cross section can be found that represents a clean 1D trace. Instead of searching for one clean cross section, the DeCoDeC algorithms extracts common peak patterns from pairs of cross sections, which can have different overlaps in the proton dimension. The resulting consensus traces or planes are more likely to represent clean 1D or 2D spectra of individual components identified through subsequent clustering. It should be noted that there is no consensus trace for 1-spin systems. Therefore, information on such systems is not tracked. Consensus trace determination can be generalized to trace triplets or even larger numbers of traces if desired. For example, in the case of trace triplets any 3-spin system will yield only a single consensus trace, which after clustering will show up as an ‘orphan’ trace in the dendrogram, while 1-spin and 2-spin systems will be lost.

Although more NMR-time consuming than the 2D methods, the 3R DeCoDeC approach disclosed here directly generates HSQC spectra of individual compounds in mixtures, which may offer several advantages. First, an HSQC is more specific than a 1D trace as spectral information is spread out in multiple dimensions. This feature makes database querying of HSQC planes more accurate than querying of 1D spectral traces. At the same time, one can retain the option to project the HSQC plane onto the proton or carbon dimension and apply a 1D query. Secondly, clustering of HSQC planes enhances the separation of the cluster centers, which helps visual inspection of the dendrogram for the extraction of a representative HSQC plane for every cluster.

HSQC planes reconstructed by the new method carry their original intensities from the input HSQC spectrum H, therefore they can be used for the quantification of compound concentrations. Moreover, the concentration measurement for an individual metabolite can be improved by averaging the intensities of multiple, non-overlapping cross-peaks assigned to that metabolite. Since HSQC is deficient in connectivity information across complete spin systems, it is not known which peaks can be averaged to accurately quantify concentration of an individual compound in a complex mixture. Since 3R produces individual HSQC planes for each compound, one can average the peaks in the same HSQC plane to measure its concentration more accurately.

High resolution along the indirect ¹³C dimension is helpful for the performance of the 3R DeCoDeC method. Recently, non-uniform sampling schemes have been introduced to shorten the total acquisition time for 2D HSQC(-TOCSY) by reducing the number of increments along the indirect dimension while maintaining a high digital resolution (see Hyberts et al. J. Am. Chem. Soc. 2007, 129, 5108-5116). These methods can be used to shorten the total NMR measurement time, while keeping the spectral resolution sufficiently high. Finally, the 3R DeCoDeC method can be implemented for other pairs of 2D spectra, such as HMBC and HSQC, TOCSY and HSQC or even 2D HSQC-TOCSY and HMBC to obtain HMBC planes of individual compounds in complex mixtures.

New 2D and 3R NMR strategies have been disclosed for the analysis of complex chemical mixtures to obtain information about the components in a reliable, efficient, and automatable fashion. The 2D DeCoDeC approach permits the determination of 1D ¹H spectra of individual components while the 3R DeCoDeC method extracts 2D ¹³C-¹H HSQCs of individual components, which serve as useful fingerprints for database queries and as entry points to chemical structure determination. The 2D TOCSY, 2D HSQC-TOCSY, and 3R HSQC-TOCSY spectra require increasing amounts of measurement times, but they provide increasingly good deconvolution performance when applied to mixtures of higher complexity. Together these new tools and processes open up the prospect to enable routine yet accurate analysis of an increasingly complex and diverse range of molecular solutions.

### II. ^{D}C-Enriched 2D NMR Methods

### Identification of Constant-Time ¹³C-¹³C TOCSY NMR Traces Followed by Consensus Clustering

In this aspect of the disclosure, we characterize the metabolome of a cell by a novel homonuclear ¹³C₂D NMR approach applied to a non-fractionated uniformly ¹³C-enriched lysate of E. coli cells and determine de novo their carbon backbone topologies that constitute the “topolome”. A protocol was developed, which first identifies traces in a constant-time ¹³C-¹³C TOCSY NMR spectrum that are unique for individual mixture components and then assembles for each trace the corresponding carbon-bond topology network by consensus clustering. By way of example, this method led to the determination of 112 topologies of unique metabolites from a single sample, and the topolome was found to be dominated by carbon topologies of carbohydrates (34.8%) and amino acids (45.5%) that can constitute building blocks of more complex structures

Spectral Analysis.

The deconvolution of the 2D ¹³C-¹³C CT-TOCSY, represented by a N₁×N₂ matrix T, of the ¹³C-labeled cell lysate was performed by adapting the DeCoDeC approach to ¹³C-¹³C TOCSY (DeCoDeC stands for Demixing by Consensus Deconvolution and Clustering (see: Bingol and Brüschweiler, Anal. Chem. 1, 83, 7412-7417 (2011)). Peak picking of the cross-peaks of matrix T yielded a list (k,k′) where k and k′ denote the cross-peak position along the two frequency axes. In order to minimize the influence of those parts of T that are close to the diagonal, the intensities of all diagonal peaks were set to the largest peak intensity of the rest of the spectrum (see infra). Next, for each cross-peak pair (k,k′) and (l,l′), which are placed symmetrically with respect to the diagonal, the k^{th} and l^{th} row are extracted from T to obtain the consensus trace, defined as:

qⱼ^{(kl)}=min(Tₖⱼ,Tₗⱼ) (5)

wherein index j=1, . . . , N₂. The enlargement of the diagonal peaks of T ensures that Eq. (5) is dominated by cross-peaks rather than diagonal peaks. The complete set of consensus traces q^{(kl)} was subsequently subjected to clustering for the identification of those traces that represent 1D ¹³C spectra of individual spin systems. For this purpose, 1D ¹³C consensus traces q^{(kl)} were quantitatively compared to each other via the inner product:

$${P}_{kl , mn} = {\sum }_{j = 1}^{{N}_{2}} {q}_{j}^{( kl )} {q}_{j}^{( mn )} / ( ‖ {q}^{( kl )} ‖ \cdot ‖ {q}^{( mn )} ‖ ) \qquad ( 6 )$$

wherein the L2-norm of a consensus trace is given by:

$$‖ {q}^{( kl )} ‖ = {[ {\sum }_{j = 1}^{{N}_{2}} {( {q}_{j}^{kl} )}^{2} ]}^{1 / 2} \qquad ( 7 )$$

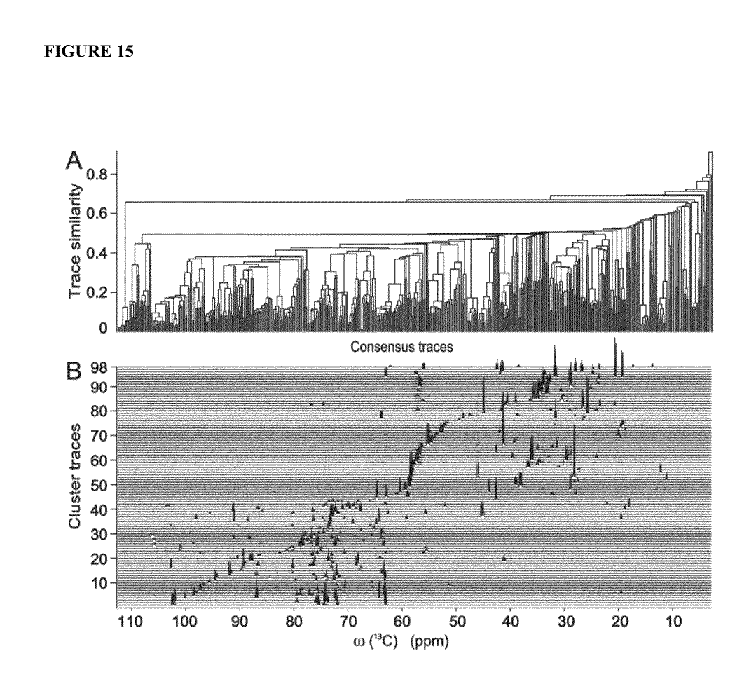

Thus, 1−P_{kl,mn} defines a similarity measure between pairs of traces, which permits clustering, e.g., using the agglomerative hierarchical cluster algorithm as implemented in the subroutine “linkage” of the MATLAB® software package. The clustering result can be displayed as a dendrogram, for example, as shown in FIG. 15.

CT-TOCSY Spectrum Reconstruction from Cluster Center Traces.

To each cluster center trace along ω₂, tₘ^{(r)} (where superscript r denotes a row vector), the corresponding CT-TOCSY trace along ω₁ was assigned represented by the column vector tₘ^{(c)} (where superscript c denotes a column vector). If tₘ^{(r)} is the consensus trace between the k^{th} and l^{th} row of T, then tₘ^{(c)} is simply the consensus trace between the k′^{th} and l′^{th} columns where (k,k′) and (l,l′) denote the corresponding cross-peak pair (see supra). Next, for each trace pair tₘ^{(r)} and tₘ^{(c)}, the two N₁×N₂ correlation spectra were reconstructed according to:

Sₘ=tₘ^{(c)}·tₘ^{(r)} and Sₘ^{(cc)}=tₘ^{(c)}·tₘ^{(c)}^{^{T}} (8)

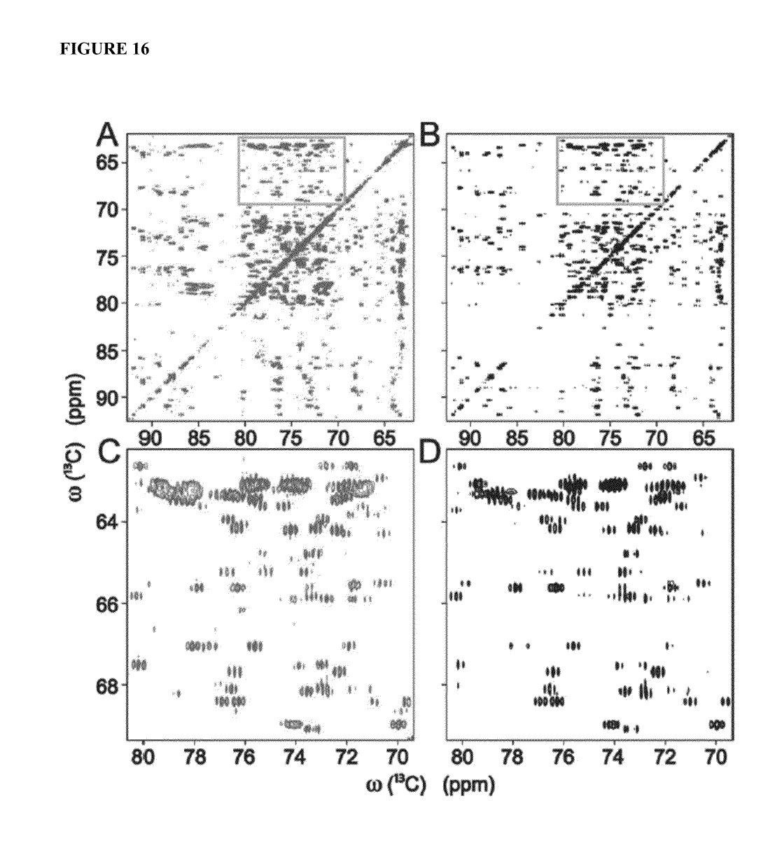

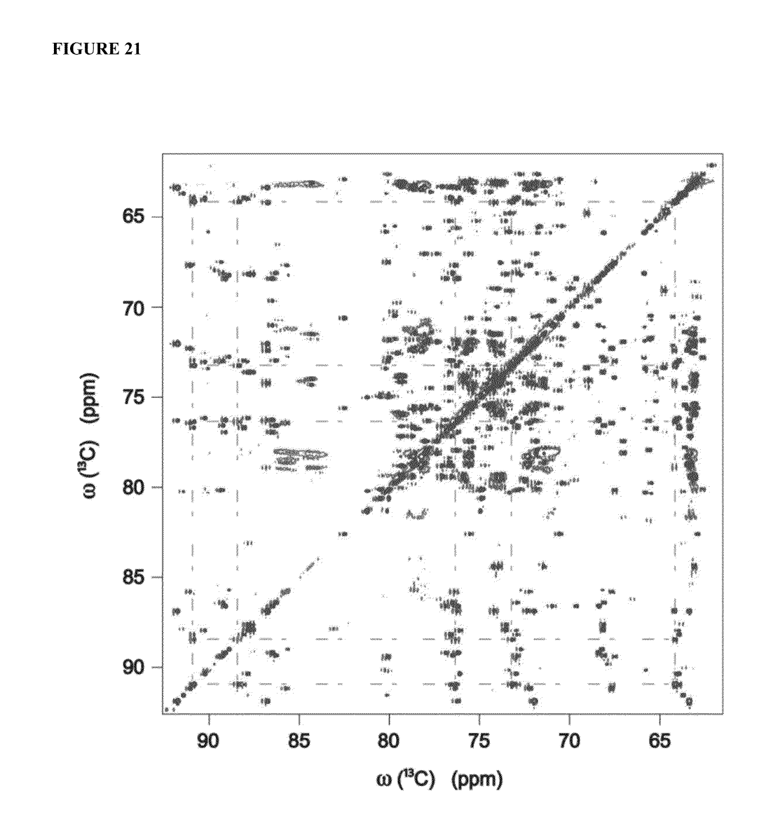

and superimposed on the TOCSY spectrum for cross-peak assignment and validation. Since tₘ^{(c)} is decoupled by the constant-time TOCSY scheme, Sₘ^{(cc)} has a collapsed multiplet structure, and hence high resolution, along both dimensions. By contrast, Sₘ is only decoupled along ω₁, while it shows the full multiplet fine structure along ω₂ (see FIG. 16). The cross-peak fine structure of Sₘ equals the one of the experimental CT-TOCSY trace along ω₂, while Sⱼ^{(cc)} has its collapsed cross-peaks centered at the same positions as Sₘ. FIG. 21 depicts regions of

S^{(cc)}=Σₘ₌₁^{M}Sₘ^{(cc)} (9)

where M is the total number of compounds (spin systems) superimposed on T with the dashed lines connecting the ¹³C-¹³C cross-peaks of selected spin systems.

Non-Uniform ¹³C Enrichment.

A uniformly high level of ¹³C enrichment is very helpful for the method to work well. This is because low ¹³C enrichment levels will reduce the number of fully, i.e. consecutively, ¹³C-labeled spin systems, which is required for the extraction of complete spin system information from CT-TOCSY traces. If the fraction of ¹³C labels at all sites is 0<f<1, then the fraction of fully labeled molecules is f^{N}, where N is the number of spins. Hence, the number of molecules that contribute to complete TOCSY traces decreases exponentially with N, which is accompanied by a corresponding drop in sensitivity. If the enrichment level is biochemical pathway related, as is typical for mammalian cells, f can be close to 0 for certain sites and possibly impede the measurement of complete carbon traces by this approach.

Results of New ¹³C-Enriched Methods

Referring to the Figures, results of the disclosed comprehensive approach for the characterization of the metabolic content of uniformly ¹³C-enriched cells based on homonuclear 2D ¹³C NMR are demonstrated.

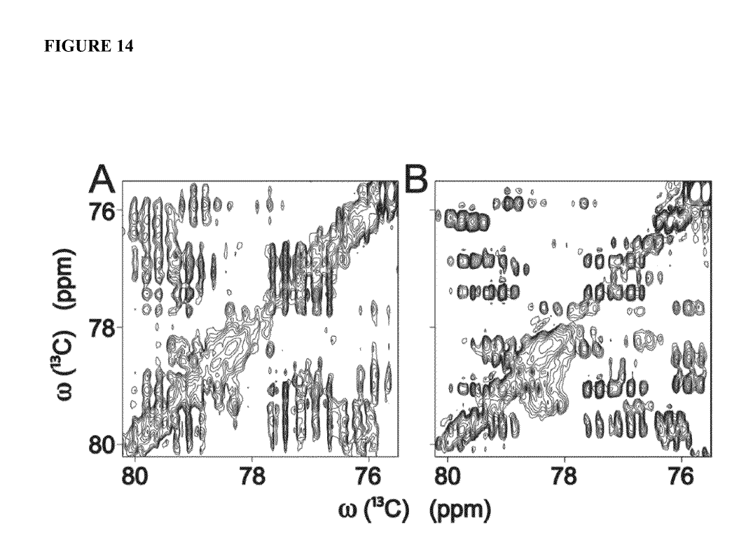

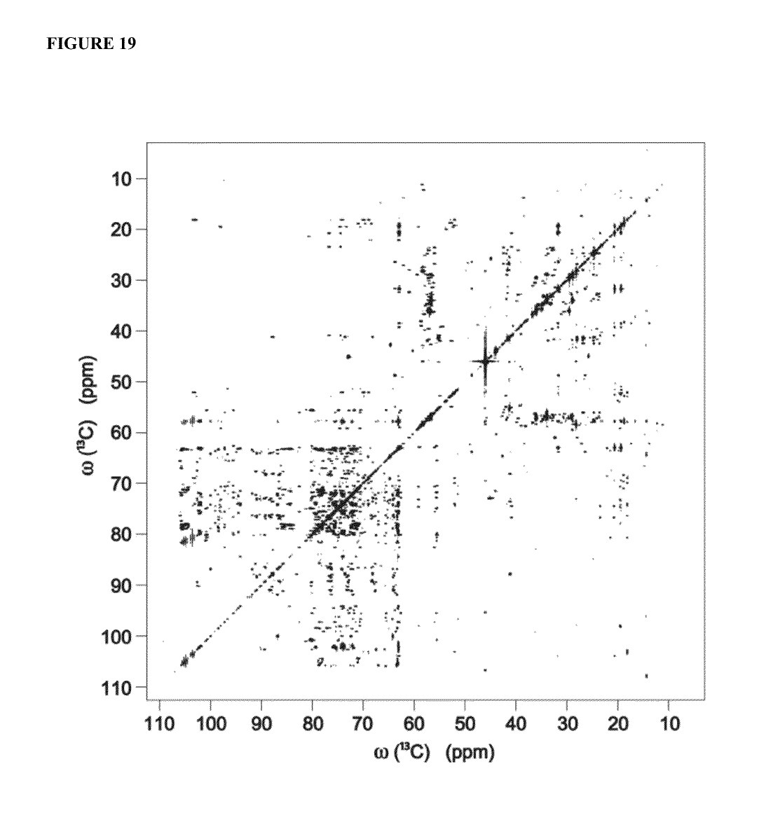

Referring to the figures, FIG. 14 compares a spectral region of E. coli cell lysate of a 2D ¹³C-¹³C CT TOCSY with a regular 2D ¹³C-¹³C TOCSY (FIG. 19 shows the full CT-TOCSY spectrum), to demonstrate the methods of this disclosure. The presence of homonuclear ¹J(¹³C,¹³C)-couplings leads to prominent peak splittings with average multiplet widths of ˜75 Hz, which substantially exceed the intrinsic linewidths. In the regular 2D TOCSY methods, these splittings appear along both frequency dimensions leading to severely congested cross-peak regions (see FIG. 14A). By contrast, the CT-TOCSY (FIG. 14B) method according to this disclosure provides data that are decoupled along the ω₁ dimension with respect to the dominant ¹J(¹³C,¹³C)-couplings and therefore displays significantly reduced cross-peak overlap. The resolution enhancement along ω₁ over the standard 2D ¹³C-¹³C TOCSY amounts on average to a factor greater than about 4 (>4), improving the average multiplet width from >70 Hz to approximately 15 (˜15) Hz, which greatly aided in the analysis of a spectrum of the complexity of a cell lysate.

In another aspect, for example, favorable resolution achieved in this way generally is not a limiting factor for the analysis of complex mixtures. According to other embodiments, the analysis of some highly complex mixtures, such as for example, carbohydrate mixtures, also can be subjected to partial fractionation prior to the NMR experiments. In this embodiment, the complexity of the analysis can be simplified somewhat.

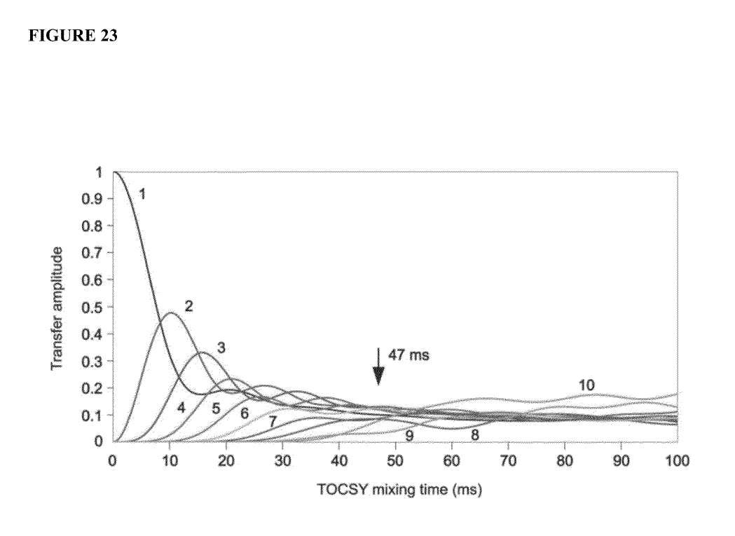

The TOCSY spectrum with a sufficiently long mixing time correlates ¹³C spins within the same spin system with each other. For linear spin systems, the transfer efficiency over ˜10 ¹³C spins is quite efficient for the mixing time of 47 ms used in the data presented in FIG. 23. In principle, and while not limited by theory, a cross-section through a cross-peak along ω₂ (ω₁) represents the homonuclear (de)coupled ¹³C₁D spectrum of the corresponding spin system. However, full or partial peak overlap along one of the frequency domains produces traces that contain additional peaks, which stem from nearby cross-peaks of other mixture components. For more complex mixtures the extraction of “pure” traces is increasingly difficult because of the higher likelihood of peak overlaps in these mixtures. To minimize spurious peaks in CT-TOCSY cross sections, a filtering procedure (DeCoDeC) was applied, which generates from a pair of TOCSY traces a consensus trace that contains only peaks that appear in both original traces. (For a full discussion, see Bingol and Brüschweiler, Anal. Chem. 2011, 83, 7412-7.) The consensus trace is notably more robust with respect to partial or complete peak overlaps than either one of the input traces (infra). The two input traces were taken as cross sections along ω₂ through cross-peaks symmetrically placed with respect to the diagonal. The resulting set of consensus traces was then subjected to hierarchical clustering as visualized by the dendrogram in FIG. 15A. It permits the straightforward extraction of cluster centers that represent unique spin systems. In this way, as illustrated in the FIG. 15 analysis, 98 spin systems were identified, whose 1D traces are depicted in FIG. 15B. Cluster traces with a signal-to-noise ratio as low as ˜10:1 were recognized with high fidelity benefitting from the remarkably flat base plane of the ¹³C-¹³C CT-TOCSY spectrum. Unlike ¹H-detected NMR spectra, the ¹³C-¹³C CT-TOCSY spectrum does not suffer from the presence of a strong solvent peak. Remaining peaks with low signal-to-noise (due to low concentration of the corresponding compound) were manually analyzed as described hereinbelow.

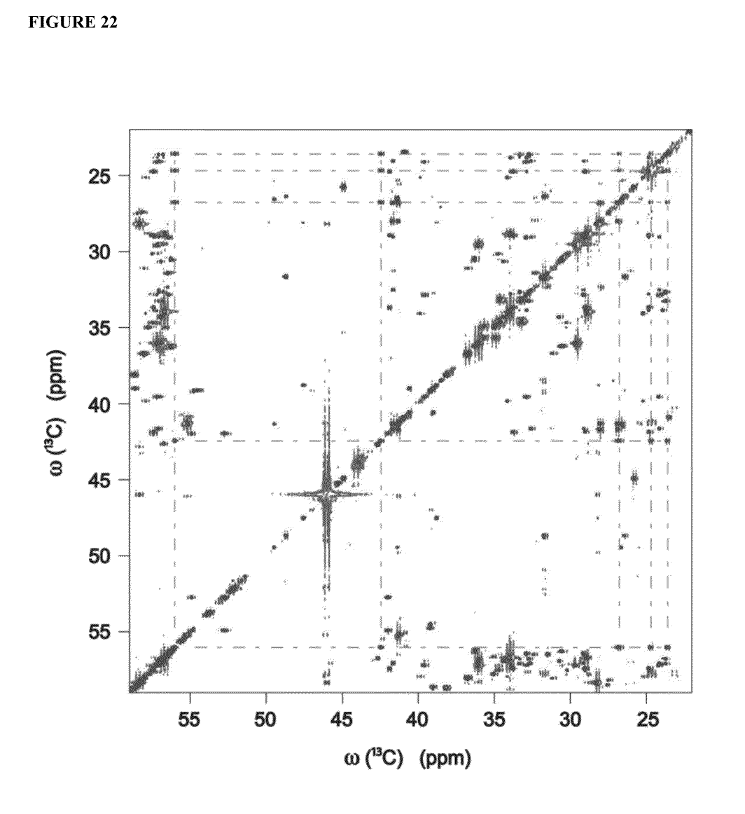

In a next step, from each cluster center trace j of FIG. 15B, a correlation spectrum Sⱼ was reconstructed containing all ¹³C-¹³C cross-peaks expected from its cluster trace as described infra. The cross-peaks of the original CT-TOCSY T could then be assigned to individual cluster center traces by direct comparison with S₁. Thus, FIG. 16 depicts selected regions of the CT-TOCSY spectrum (Panels A,C) for comparison with the superposition of all spectra Sⱼ (Panels B,D). As can be seen, very close agreement in peak positions and multiplet structure between the original and the back-calculated spectrum attest to the high degree of completeness achieved for the assignment of cross-peaks to specific spin systems. This aspect is further illustrated in FIGS. 21 and 22, which depict the connections between ¹³C-¹³C cross-peaks for the ribose of adenosine and leucine derived from the back-calculated spectra of these 2 metabolites. The cross-peaks that could not be assigned in this way have on average a signal-to-noise S/N ˜5, which is a factor 5 lower than the median S/N of the assigned peaks. Based on manual inspection of unassigned cross-peaks an additional 14 spin systems were uncovered, bringing the total number of spin systems identified in the E. coli cell lysate sample to 112.

The connectivity information of ¹³C-¹³C TOCSY spectra directly reports about covalent carbon-carbon bonds in the complex mixture. For this purpose, the short-mixing time (4.7 ms) ¹³C-¹³C CT-TOCSY spectrum (Tₛₕₒᵣₜ) was used in order to reconstruct the full carbon backbone structures (molecular topologies) of each metabolite. Because the one-bond ¹J(¹³C,¹³C)-couplings dominate the ²J(¹³C,¹³C) and ³J(¹³C,¹³C) couplings, a cross-peak in Tₛₕₒᵣₜ is direct evidence for the presence of a chemical bond between two carbon atoms. When superimposing a correlation spectrum Sⱼ, reconstructed from cluster center trace j on Tₛₕₒᵣₜ, the cross-peaks of Sⱼ that coincide with a cross-peak in Tₛₕₒᵣₜ represent a carbon-carbon chemical bond, while ¹³C pairs that do not show a cross-peak in Tₛₕₒᵣₜ do not have a chemical bond between each other.

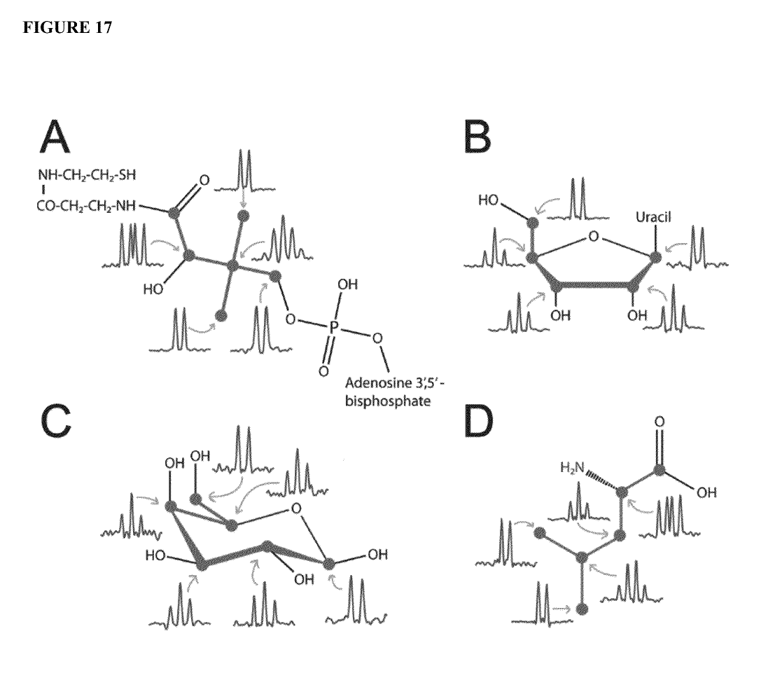

Since the TOCSY spectrum did not cover the carbonyl and carboxyl ¹³C resonances (˜176 ppm) due to ¹³C radio-frequency offset effects, we used the ¹³C-¹³C COSY to establish connectivities to those carbon moieties. From the chemical bond information derived from the Sⱼ spectra, a bond connectivity matrix was derived for each consensus trace, which was then converted into the topology network by graph theory (FIG. 17). To independently validate the topologies obtained in this way, the multiplet structure of each TOCSY cross-peak was examined. Carbons that are bonded to one, two, three, or four other carbons show the characteristic multiplet patterns with intensity ratios 1:1, 1:2:1 (or 1:1:1:1), 1:3:3:1, and 1:4:6:4:1, respectively. As is demonstrated in FIG. 17 for coenzyme A, the ribose of uridine, β-galactose and leucine, the multiplet patterns provide a rigorous consistency test of the topologies without requiring any additional experiment.

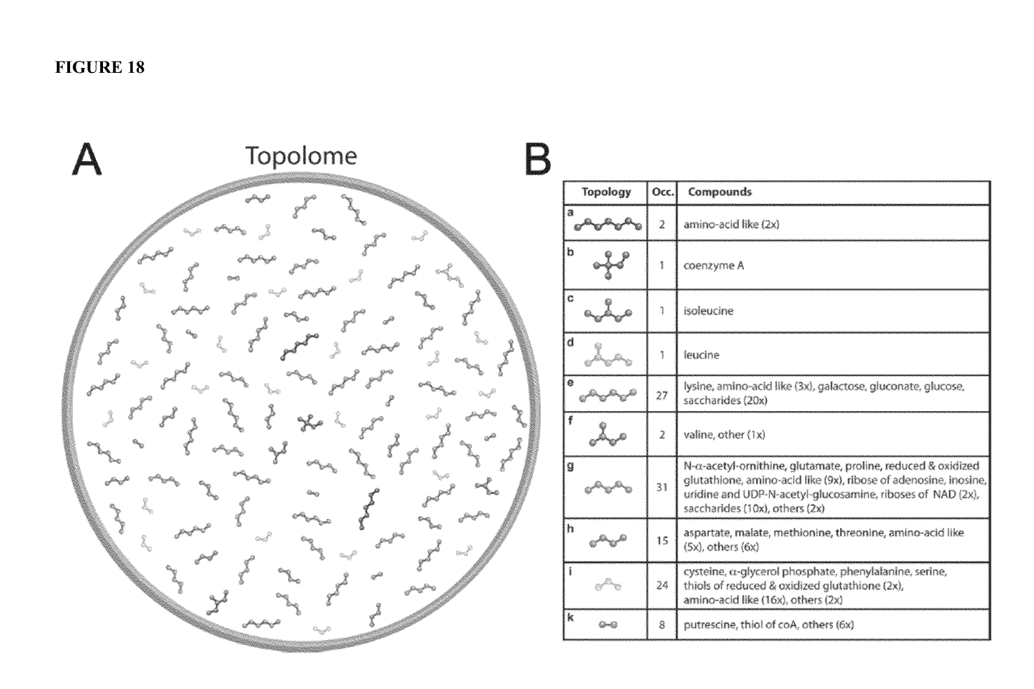

All 112 identified metabolite topology networks were tested for consistency in this manner. The sum of all topologies, termed the metabolite “topolome”, is depicted in FIG. 18A. The metabolite topolome contained 10 different topology types (FIG. 18B), which include up to 7 carbons. Note that topologies with a single carbon are not included here because they do not give rise to a ¹³C TOCSY or COSY cross-peak. The observed occurrences of each topology, listed in FIG. 18B, range between 1 (topologies b,c,d) and 31 (topology g), FIG. 18B. These topologies refer to the carbon spin systems only. For example, the carbon spin system of ribose is linear while its chemical structure is cyclic whereby the ether linkage prevents magnetization transfer between oxygen-linked carbons. Secondary carbons are encountered most often with a relative occurrence of 54%, followed by primary carbons (topological end groups) (45%), tertiary carbons (0.8%), and quarternary carbons (0.2%). The most frequent topology consists of 5 linearly arranged carbons (topology g), whereas the ‘average’ topology has 4.5 linearly arranged carbon atoms. The topolome was then linked to known molecules by screening each cluster center trace against the 1D ¹³C spectral metabolomics library of the BioMagResDatabank (see Ulrich et al. Nucl. Acids Res. 2008, 36, D402-D408) using the COLMAR web server (see Robinette et al. Anal. Chem. 2008, 80, 3606-3611). This screening step yielded unique molecular assignments of 29 cluster traces (spin systems) belonging to 27 metabolites listed in FIG. 18B. These 27 metabolites included 12 unliganded amino acids, 6 riboses of larger nucleic-acid containing molecules, and 3 monosaccharides containing six carbons. The majority of these 27 metabolites were also observed in E. coli cell extracts by mass spectrometry. See: Bennett et al. Nat. Chem. Biol. 2009, 5, 593-9. The largest difference between the mass spectrometry and NMR results concerns carbohydrates, since the number of 6-carbon sugars detected by NMR (23 compounds) exceeds the one observed by mass spectrometry (11 compounds). While not intending to be bound by theory, it is believe that some of these carbohydrate units may be part of as yet uncharacterized or uncatalogued structures, while others may belong to isobaric isomers, whose distinction by mass spectrometry is a challenge. Discussions of these aspects can be found in, for example, Mutenda et al. Methods Mol. Biol. 2007, 367, 289-301. Thus, ¹³C-¹³C TOCSY traces of carbohydrates provide straightforward access to their carbon topologies, while chemical shift changes uniquely identify the carbon modification sites. For example, all 4 glucosamine-like topologies observed here have the nitrogens attached at their C2 positions, which is the same as for glucosamine. These differences underline the complementarity of these two experimental methods.

High-resolution solution NMR of biological mixtures typically detect hundreds to thousands of peaks of both known and unknown compounds. NMR methods can be used for a wide range of applications, including compound identification, quantification, and de novo characterization of unknown species, that cross the boundaries between traditional natural products research and metabolomics. (For a general description, see Robinette, et al. Acc. Chem. Res. 2012, 45, 288-7.) While database searching can dramatically accelerate the verification of the presence of known compounds, the characterization of unknown compounds remains a major challenge. The classical approach, which often is the method of choice in natural products research, uses chromatographic separation until individual compounds are isolated so that they can be further characterized individually. Because this approach is too time-consuming for metabolomics-type applications, methods have been needed that do not require extensive fractionation. The multidimensional NMR-based approach presented here for both types of analysis of metabolite mixtures of uniformly ¹³C-labeled organisms addresses these issues of characterization of unknown compounds without the time and expense of separation and isolation of individual compounds.

The favorable spectral resolution and baseline properties of the ¹³C-¹³C TOCSY correlation spectra disclosed herein allow a rigorous, semi-automated analysis of the mixture in terms of the carbon-backbone topologies of the underlying components with concentrations in the sub-mM to hundreds of mM range. A demonstration of the utility of this method is seen in its ability to reconstruct the full topolome consisting of 112 spin systems or chemical species detectable by NMR. From the cluster center traces, each representing a metabolite ¹³C spin system, a remarkably complete reconstruction of the CT-TOCSY could be achieved (see FIG. 16), which accounts for over 94% of all observable CT-TOCSY cross-peaks. Resonances that are not accounted for either have very low signal-to-noise ratios or they fall into the few highly crowded regions, such as the ones around 70-72 ppm and 84-86 ppm (FIGS. 16 and 19). In addition, analysis of the multiplet pattern of each ¹³C resonance permitted independent validation of each topology. Together, these methods enable the rapid and reliable identification of the very large number of topologies such as those reported here.

Among other things, this approach represents a significant advance over alternative methods of chemical structure determination in complex mixture. An additional advantage of direct ¹³C detection is that non-protonated carbons can be directly detected, including carbonyl and carboxyl carbons whose correlations with other carbons are obtained from the ¹³C-¹³C COSY. Since carbonyl and carboxyl carbons possess significantly larger ¹J(¹³C,¹³C)-couplings (˜55 Hz) than most other C—C bonds (˜35 Hz), multiplet patterns observed in CT-TOCSY independently validate the carbonyl and carboxyl substituents observed in the ¹³C-¹³C COSY experiment. For example, in FIG. 17D the resonances of leucine Cα and Cβ, which are both secondary carbons, show the distinct multiplet patterns 1:1:1:1 and 1:2:1, respectively, consistent with the attached carboxyl group to Cα.

As demonstrated in the exemplary use of this method, the topolome detected for E. coli reveals that the most frequent topology with 31 occurrences is linear containing 5 sequentially bonded carbons (topology g in FIG. 18). This topology comprises glutamate and 8 glutamate-like compounds or spin systems. It also includes 13 riboses and only 1 deoxyribose, reflecting the larger structural and functional diversity of ribose-containing molecules over deoxyribose-containing molecules. Moreover, the method differentiates between isomers that slowly interconvert on the NMR chemical shift timescale. The second most frequent topology with 27 occurrences is topology e (6 linearly arranged carbons). Topology e includes 12 aldohexoses, comprising the common monosaccharides glucose and galactose, serving both as energy sources and structural building blocks in the cell. An advantage of NMR-based topology analysis is that quantitative chemical shift information at each carbon site is available. Aldohexoses detected here generally exhibit a 5-10 ppm ¹³C chemical shift increase in the 1C or 4C positions (or both) compared to monosaccharides. Since these positions are the common glycosidic linkage sites with other molecular groups, the unknown aldohexoses might be part of larger chemical structures, such as polysaccharides (whereby the oxygens involved in these linkages divide the carbons into separate spin systems that are not connected by TOCSY cross-peaks). Certain amino sugars, such as N-acetylglucosamine and N-acetylmuramic acid present in the cell lysate in 4 different forms, share the same topology as the aldohexoses (topology e). The third most frequent topology with 24 occurrences is topology i (3 linearly arranged carbons). Topology i is adopted by 7 alanine-like compounds and topology a includes 2 diaminopimelic-acid like topologies. Because the prevalent glutamate, alanine, diaminopimelic acid, N-acetylglucosamine and N-acetylmuramic acid form the basic building blocks of the peptidoglycan cell wall of E. coli, these topologies might belong to cell wall fragments. Knowledge of metabolite topologies provides an ideal basis for further characterization. Since NMR ¹³C chemical shifts with their high sensitivity to substituents are obtained simultaneously with the topologies, they should assist further chemical structure determination of selected mixture components. The presence of substituents predicted from ¹³C chemical shifts can be corroborated by additional NMR experiments that display correlations, for example, to ³¹P, ¹⁵N, and ¹H nuclei.

The resolution power resulting from the combination of consensus trace clustering with homonuclear ¹³C CT-TOCSY spectroscopy as disclosed herein produces a unique and exhaustive set of carbon topologies of components of a mixture of ultra high complexity as demonstrated here for a uniformly ¹³C-labeled cell lysate. It is expected that this kind of information should prove powerful for the exploration and establishment of new biochemical pathways and interactions involving ¹³C-labeled endogenous and exogeneous metabolites. Uniform ¹³C-labeling of many organisms, such as bacteria, yeast and plants, is now readily available and, hence, this NMR strategy can give broad access to the complex chemical information necessary for a systems biological understanding of their function.

### Examples

### General and Reference Information

General, background, and reference information for some of the steps used in the methods disclosed herein can be found in the following references. Information concerning methods to obtain correlation information of individual spin systems using frequency-selective 1D TOCSY are reported (Sandusky et al. Anal. Chem. 2005, 77, 2455-2463; Sandusky et al. Anal. Chem. 2005, 77, 7717-7723) and for 2D TOCSY (Bodenhausen et al. Chem. Phys. Lett. 1980, 69, 185-189) in combination with clustering methods, such as DemixC (Zhang and Brüschweiler Angew. Chem. Int. Ed. 2007, 46, 2639-2642). Information concerning applying direct covariance processing to T (Brüschweiler et al. J. Chem. Phys. 2004, 120, 5253-5260 and Trbovic et al. J. Magn. Reson. 2004, 171, 277-283) with regularization (Chen et al. J. Biomol. NMR 2007, 38, 73-77) in the case of TOCSY, and indirect covariance processing (Zhang and Brüschweiler J. Am. Chem. Soc. 2004, 126, 13180-13181) in the case of HSQC-TOCSY can be found in the cited references. Information concerning filtering methods which identify mismatches between the first and second moments of cross-peak profiles can be found at (Bingol et al. J. Phys. Chem. Lett. 2010, 1, 1086-1089). Representative HSQC spectra for the following compounds are taken from the BMRB (Ulrich et al. Nucleic Acids Res. 2008, 36, D402-408) or HMDB (Wishart et al. Nucleic Acids Res. 2007, 35, D521-6) databases: cystine, valine, isoleucine, leucine, proline, glutamine, lysine, glutathione, cytosine, and 4 ribose rings corresponding to different nucleic acid forms.

The following standard abbreviations are used throughout this disclosure: 3R, triple rank; CT, Constant Time; DeCoDeC, Demixing by Consensus Deconvolution and Clustering; DemixC, Demix Clustering; TOCSY, Total Correlation Spectroscopy; HSQC, Heteronuclear Singular Quantum Correlation (or Coherence); NMR, Nuclear Magnetic Resonance; BMRB, Biological Magnetic Resonance data Bank; and HMDB, Human Metabolome DataBase.

I. Extraction of 1D Consensus Spectral Traces or 2D Consensus Planes Followed by Clustering.

Examples provided. This section of the disclosure describes experiments illustrating the application of DeCoDeC to covariance ¹H-¹H TOCSY and ¹³C-¹H HSQC-TOCSY, and 3R DeCoDeC to the triple-rank spectrum constructed from the 2D ¹³C-¹H HSQC and 2D ¹³C-¹H HSQC-TOCSY spectra of the model mixture, as further illustrated by three (3) figures. Also illustrated are two (2) figures with 1D reference ¹H spectra from the BMRB for compounds mentioned in the specification. The full ¹H 1D spectra of shikimate and ribose ring of adenosine obtained by 2D DeCoDeC is also illustrated, as well as the DemixC results of the model mixture and the cell lysate covariance 2D ¹H-¹H TOCSY spectrum. Finally, the 1D ¹H NMR spectrum of cell lysate is provided for comparison.

### Consensus Plane Inferencing and Clustering of Triple-Rank Correlation Spectrum

A triple-rank spectrum R is a mathematical reconstruction of a 3D spectrum from a pair of standard 2D FT spectra that share a common frequency dimension. The main advantage of the 3R spectrum over a 3D FT spectrum is the resolution gain in the indirect dimensions, which are inherited from the pair of 2D FT spectra used for reconstruction. Acquisition of two high-resolution 2D spectra takes much less time than the acquisition of the corresponding high-resolution 3D FT spectrum. In the absence of peak overlap along the shared dimension of the 2D FT spectra pair, the 3D FT and 3R spectra are equivalent. In the presence of peak overlaps, the 3R spectrum contains extraneous peaks, which can be removed in many cases by identifying mismatches between the first and second moments (i.e., line positions and linewidths) of cross-peak profiles. For a more detailed discussion, see Bingol et al. J. Phys. Chem. Lett. 2010, 1, 1086-1089, which is hereby incorporated by reference in its entirety.

A triple-rank spectrum R is constructed from the 2D ¹³C-¹H HSQC spectrum, represented by the N₁×N₂ matrix H, and the 2D ¹³C-¹H HSQC-TOCSY spectrum, represented by the N₁×N₂ matrix T, where N₂ is the number of points along the direct ¹H dimension and N₁ is the number of points along the indirect ¹³C dimension

Rₖᵢₕ=HₖᵢTₖⱼ (10)

R can be considered as a collection of 2D ¹³C-¹H HSQC spectra (with indices k, i for their ¹³C and ¹H dimensions, respectively) along the additional proton dimension j of the 2D ¹³C-¹H HSQC-TOCSY spectrum. Hence, a spin system with N_{P} protons will be represented in R by N_{P} HSQC planes. The task at hand was to extract for each spin system its unique HSQC spectrum. This was accomplished by the establishment of consensus HSQC planes, followed by clustering with the cluster centers chosen to represent HSQC spectra of the corresponding spin systems.

The following preparatory data processing steps helped to improve the robustness of the approach with respect to cross-peak overlaps.

1. Spectra H and T were represented by the absolute values of their elements and subsequently subjected to t₁-noise reduction and thresholding. A matrix element ki was set to zero if it was smaller than 5 times the average of column i or 3 times the average of row k, otherwise the matrix element remained unchanged. In Eq. (10), T is represented as a binary matrix (i.e. all non-zero elements were set to 1) so that (semi-) quantitative intensity information of the peaks in the original 2D ¹³C-¹H HSQC spectrum was directly transferred to the 2D ¹³C-¹H HSQC spectra of individual components obtained from the 3R spectrum.

2. To minimize the effects of partial peak overlap, which can lead in Eq. (10) to the appearance of false cross-peaks, we applied moment filtering as described previously (Bingol et al. J. Phys. Chem. Lett. 2010, 1, 1086-1089), except that it is applied along the ¹³C dimension (i.e. common index k in Eq. (10)). Briefly, local 1st moments are determined as follows:

$$\begin{matrix}{μ}_{H , ki} = {\sum }_{m = - M}^{M - 1} ( k + m ) {H}_{k + m , i} / {\sum }_{m = - M}^{M - 1} {H}_{k + m , i} & ( 11 ) \\ {μ}_{T , kj} = {\sum }_{m = - M}^{M - 1} ( k + m ) {T}_{k + m , j} / {\sum }_{m = - M}^{M - 1} {T}_{k + m , j} & ( 12 )\end{matrix}$$

where 2M was set to 4 (corresponding to 29.2 Hz) so that it exceeds a typical ¹³C linewidth determined by the finite digital resolution along ω₁. This moment information was then used to eliminate false peaks if the difference in their 1^{st} moment exceeds 4.4 Hz.

3. The number N₂(N₂+1)/2 of possible pairwise comparisons of HSQC planes in R is of the order of 10⁶ and hence computationally significant. Since many of these comparisons involve planes that are void of any signal, the number of comparisons can be reduced by selecting only pairs of planes with ¹H indices (j,j′) that belong to the same spin system. Such information could be obtained directly from a 2D ¹H-¹H TOCSY spectrum, which can be measured separately or, alternatively, can be constructed from the 2D ¹³C-¹H HSQC-TOCSY spectrum T already available via covariance processing C=(T^{T}T)^{1/2}. (See: Brüschweiler et al. J. Chem. Phys. 2004, 120, 5253-5260 and Trbovic et al. J. Magn. Reson. 2004, 171, 277-283.) Cross-peak picking of C leads to the list of ¹H index pairs (j,j′) that is used in the next step for the pairwise comparison of HSQC planes of R.

4. For each ¹H index pair (j,j′) of step 3, a new consensus HSQC plane is computed as follows, representing the element-by-element geometric averages:

Qₖᵢ^{(jj′)}=(Rₖᵢⱼ·R_{kij′})^{1/2} (13)

Each plane Qₖᵢ^{(jj′)} only includes spectral features that are present in both planes j and j′ of R and hence they are purged of spurious effects from overlapping protons. The planes are then stored as binary matrices where elements above the noise are set to one and otherwise set to zero.

5. The planes of Eq. (13) are compared to each other via the inner product

$${P}_{{jj}^{′} , {nn}^{′}} = {\sum }_{k , i = 1}^{{N}_{1} , {N}_{2}} {Q}_{ki}^{( {jj}^{′} )} {Q}_{ki}^{( {nn}^{′} )} / ( ‖ {Q}^{( {jj}^{′} )} ‖ \cdot ‖ {Q}^{( {nn}^{′} )} ‖ ) \qquad ( 14 )$$

where the L2-norms of the consensus planes are given by

$$‖ {Q}^{( {jj}^{′} )} ‖ = {[ {\sum }_{k , i = 1}^{{N}_{1} , {N}_{2}} {Q}_{ki}^{( {jj}^{′} )} {Q}_{ki}^{( {jj}^{′} )} ]}^{1 / 2} \qquad ( 15 )$$

As for the 2D DeCoDeC case (Eq. (2)), a similarity measure between pairs can be defined as 1−P_{jj′,nn′}, which permits clustering, e.g. using the agglomerative hierarchical cluster algorithm with the result displayed as a dendrogram. Herein, we refer to this approach as 3R DeCoDeC.

### Sample Preparation

A model mixture was prepared in D₂O solution with 8 components, where carnitine, alanine, isoleucine, ornithine, arginine, lysine, and shikimate are 10 mM each and glutamate is 1 mM (to introduce a 10-fold dynamic range).

An extract from E. coli BL21(DE3) strain was obtained as follows. The cells were cultured in M9 medium with glucose (natural abundance, 5 g/L) at 37° C., at 250 rpm. At OD 600 of 3.25, 9.5 L of cells were exposed to freeze-thaw procedure 3 times in 95 ml of water. The sample was centrifuged at 12000 rpm at 4° C. for 15 min to remove the cell debris. The supernatant was treated with sequentially added cold methanol and cold chloroform at final ratio 1(water):1(methanol):1(chloroform). See: Hyberts et al. J. Am. Chem. Soc. 2007, 129, 5108-5116. The sample was vortexed after the addition of each solvent. The resulting mixture was centrifuged at 12,000 rpm at 4° C. for 20 min for phase separation. The aqueous phase was dried under a rotary evaporator and dissolved in 2% H₃PO₄ in H₂O and loaded onto a solid phase extraction cation-exchange column (Oasis Plus MCX, Waters). The elution was dried in a rotary evaporator and dissolved in D₂O. The final samples were transferred to a 5-mm NMR tube.

### NMR Experiments and Processing

2D ¹H-¹H TOCSY spectra were collected for both samples with N₁=512 and N₂=1 024 complex data points. The spectral width for the indirect and the direct ¹H dimensions were 7002.2 Hz and 7002.8 Hz, respectively. The number of scans per t₁ increment was set to 16 for the model mixture and 32 for the cell extract. The transmitter frequency offset was set to 4.7 ppm in both ¹H dimensions.

2D ¹³C-¹H HSQC and 2D ¹³C-¹H HSQC-TOCSY data sets were collected for both samples with N₁=2048 and N₂=1024 complex data points. The transmitter frequency offset was set to 4.7 ppm in the ¹H dimension and 85.0 ppm in the ¹³C dimension. For both samples the spectral width for the ¹³C dimension was 29934.5 Hz and for the ¹H dimension 7002.8 Hz. The number of scans per t₁ increment for the model mixture was set to 8 for ¹³C-¹H HSQC and to 16 for ¹³C-¹H HSQC-TOCSY to compensate for the lower sensitivity of the latter caused by TOCSY mixing. The number of scans for the cell extract was set to 16 for ¹³C-¹H HSQC and 32 for ¹³C-¹H HSQC-TOCSY. The TOCSY mixing times were set to 90 ms for both ¹³C-¹H HSQC-TOCSY and ¹H-¹H TOCSY. The pulse length of the hard 90° degree pulse was first calibrated and then used to calibrate the power level for TOCSY mixing, which is important for the most effective magnetization transfer during TOCSY. All NMR spectra were collected using a cryoprobe at 700 MHz proton frequency at 298 K. The NMR data was zero-filled, Fourier transformed, phase and baseline corrected using NMRPipe software and converted to a MATLAB®-compatible format for further processing and analysis. The total NMR collection time for the cell lysate was 5 days, while most components could be identified with a measurement time of less than 2 days.

### Quantification and Sensitivity Considerations

The amplitudes of the consensus traces are directly proportional to the metabolite concentrations. This also applies to the consensus HSQC planes because the underlying HSQC-TOCSY spectrum in Eq. (10) is represented as a binary matrix: since only matrix H scales with concentration, but not T, the product of Eq. (10) is proportional to the concentration.

Although the primary focus of this disclosure lies on the identification of NMR spin systems as fingerprints of individual chemicals in the mixture rather than on the determination of relative or absolute concentrations, subsequent analysis can be performed for concentration determination from HSQC-type spectra. In the TOCSY- and HSQC-TOCSY-based methods, peak intensities depend on the mixing time as well as the spin-topology network, which makes absolute quantification of concentrations less straightforward. One possibility is the comparison of the consensus traces with the 1D ¹H spectrum of the mixture to identify (at least) one non-overlapping peak, which can be integrated in standard fashion for quantification. Components that are successfully identified in TOCSY-type and HSQC spectra of the cell lysate have >100 μM concentration in a 600 μl sample volume using a 5 mm NMR tube.

Because discrimination between a real peak and t₁ noise is not straightforward, consensus traces of lower concentration solutes may contain t₁ noise from peaks belonging to solutes present at higher concentration. This situation arises for glutamate (FIG. 4C) whose consensus trace contains a t₁-noise peak at 3.1 ppm. Since the other compounds in the model mixture have 10-fold higher concentration, t₁ noise is less apparent than in the glutamate case. For additional comparisons, the reference 1D ¹H spectra of the 8 compounds in the model mixture are shown in FIG. 7.

In order to successfully perform computation of the triple-rank spectrum, the two spectra were properly aligned along the indirect ¹³C dimension, which is the dimension they both share. Individual ¹³C-¹H HSQC planes in FIGS. 6C,E correspond to Q planes calculated by using two different ¹H index pairs (j,j′) in Eq. (13). As can be seen in FIG. 6B, there are peak overlaps along both the ¹H dimension and the ¹³C dimension. To suppress artifacts along the ¹³C dimension, filtering is applied (see Eqs. (11,12)), which identifies a potential mismatch between the l^{st} moments of the carbon resonances of input spectra H and T. Note that the 2^{nd} moments were not used for filtering, since the peaks along the ¹³C dimension are all decoupled and have similar shapes, in contrast to the ¹H peaks. To suppress artifacts due to overlaps along the ¹H dimension, a consensus procedure is applied as follows. For spectra where overlaps along the proton dimension are common, it is unlikely that a clean HSQC plane can be obtained for every compound as a cross section of the 3R spectrum at a given index j (see Eq. (10)). Therefore, for each pair of HSQC planes at proton frequencies j and j′ the element-by-element geometric average determines a consensus plane (Eq. (13)). This step retains those peaks that are present in both HSQC planes and suppresses peaks that appear only in one of them. Hence, the effect is similar to the minimum pair extraction used for pairs of traces of individual 2D spectra (Eq. (1)). To identify a manageable set of candidate (j,j′) pairs, a peak picking procedure is performed on a homonuclear ¹H-¹H TOCSY-type spectrum, which can be an experimental ¹H-¹H TOCSY spectrum or a (direct) covariance processed 2D ¹³C-¹H HSQC-TOCSY spectrum. In order to minimize the required experimental NMR time, a covariance processed 2D ¹³C-¹H HSQC-TOCSY spectrum is employed here. After obtaining all consensus planes Q, they are compared via the inner product (Eq. (14)) for subsequent clustering. Since the (j,j′) pairs are derived from TOCSY cross-peaks, most of them belong to the same compound and therefore most consensus planes Q will include spectral features of individual compounds only. This improves the clustering of the HSQC consensus planes and thereby facilitates the selection of representative HSQCs of individual components. Currently the method requires a 2D HSQC and a 2D HSQC-TOCSY spectrum as input. To reduce acquisition time, alternative data acquisition schemes are conceivable, such as the PANACEA approach, which acquires two different 2D experiments in parallel (Kupce, E.; Freeman, R. J. Am. Chem. Soc. 2008, 130, 10788-10792).

II. Constant-Time ¹³C-¹³C TOCSY NMR Traces Followed by Consensus Clustering

Examples provided. This section further discloses and illustrates the application of the novel homonuclear ¹³C₂D NMR approach to characterize the metabolome of a cell when applied to a non-fractionated uniformly ¹³C-enriched lysate of E. coli cells. Further described here is the determination de novo of the carbon backbone topologies that constitute the topolome. The protocol first identified traces in a constant-time ¹³C-¹³C TOCSY NMR spectrum that were unique for individual mixture components and then assembled for each trace the corresponding carbon-bond topology network by consensus clustering.

Sample preparation. BL21(DE3) cells were cultured in M9 minimum medium as previously described (see: Bingol and Brüschweiler, Anal. Chem. 2011, 83, 7412-7417; Zhang and Brüschweiler, Angew. Chem. Int. Ed. 2007, 46, 2639-2642; and Hyberts et al. J. Am. Chem. Soc. 2007, 129, 5108-5116) with [U-¹³C]glucose added as sole carbon source. One liter of overnight BL21(DE3) culture was centrifuged at 5000×g for 20 min at 4° C., and the cell pellet was resuspended in 50 mL of 50 mM phosphate buffer at pH 7.0. Cell suspension was then subjected to centrifugation for cell pellet collection. The cell pellet was resuspended in 60 mL of ice cold water, and pre-chilled methanol and chloroform were sequentially added under vigorous vortex at H₂O:methanol:chloroform ratios of 1:1:1. The mixture was then left at −20° C. overnight for phase separation. Next, the mixture was centrifuged at 4000×g for 20 min at 4° C., and the clear, top hydrophilic phase was collected and subjected to rotary evaporator processing to have the methanol content reduced. Finally, the liquid was lyophilized. The NMR sample was prepared by dissolving the lyophilized material in D₂O.

NMR experiments. 2D ¹³C-¹³C CT-TOCSY data sets were collected with 576×2048 (N1×N₂) complex points with a long (47 ms) and a short (4.7 ms) mixing time, respectively, using FLOPSY-16 with 22 h measurement time and a digital resolution of 38 Hz along ω₁ prior to zero filling. (See, for example, Kadkhodaie, et al., J. Mag. Reson. 1991, 91, 437-443.) Standard 2D ¹³C-¹³C TOCSY data were collected with 512×2048 (N₁×N₂) complex points using a 46 ms mixing time using DIPSI-2 for mixing. (See Shaka, A. J.; Lee, C. J.; Pines, A. J. Mag. Reson. 1988, 77, 274-293.) Both 2D ¹³C-¹³C CT-TOCSY and 2D ¹³C-¹³C TOCSY were collected with 110 ppm ¹³C spectral width. The 2D ¹³C-¹³C COSY data set was collected with 1024×1024 (N₁×N₂) complex data points with 202.5 ppm ¹³C spectral width.

All NMR spectra were collected at 800 MHz proton frequency at 25° C. The NMR data were zero-filled, Fourier transformed, phase and baseline corrected using NMRPipe (see Delaglio, et al., J. Biomol. NMR 1995, 6, 277-93) and converted to a MATLAB®-compatible format for subsequent clustering and analysis.

CT-TOCSY spectrum reconstruction from cluster center traces. For each cluster center trace along ω₂, tⱼ^{(r)} (where superscript r denotes a row vector), the corresponding CT-TOCSY trace along ω₁ was selected, which is represented by the column vector tⱼ^{(c)} (where superscript c denotes a column vector). For each trace pair (tⱼ^{(r)}, tⱼ^{(c)} a N₁×N₂ correlation spectrum was reconstructed according to Sⱼ=tⱼ^{(c)·t}ⱼ^{(r)} and superimposed on the TOCSY spectrum for cross-peak assignment and validation. Since tⱼ^{(c)}, but not tⱼ^{(r)}, is decoupled because of the constant-time TOCSY scheme, Sⱼ is also decoupled along ω₁ while it shows the full multiplet fine structure along ω₂. Therefore, the peak positions and cross-peak fine structures of Sⱼ are identical to the ones of the experimental CT-TOCSY spectrum. Comparison of the sum of all sub-spectra over all M compounds (spin systems), S=Σⱼ₌₁^{M}Sⱼ, with the CT-TOCSY spectrum shows the near completeness of CT-TOCSY cross-peak assignment of the E. coli cell lysate (FIGS. 16B,D).

Each of the references or citations provided in this disclosure is incorporated herein by reference in pertinent part. To the extent that any definition or usage provided by any document incorporated by reference conflicts with the definition or usage provided herein, the definition or usage provided herein controls. In any application before the United States Patent and Trademark Office, the Abstract of this application is provided for the purpose of satisfying the requirements of 37 C.F.R. §1.72 and the purpose stated in 37 C.F.R. §1.72(b) “to enable the United States Patent and Trademark Office and the public generally to determine quickly from a cursory inspection the nature and gist of the technical disclosure.” Therefore, the Abstract of this application is not intended to be used to construe the scope of the claims or to limit the scope of the subject matter that is disclosed herein. Moreover, any headings that are employed herein are also not intended to be used to construe the scope of the claims or to limit the scope of the subject matter that is disclosed herein. Any use of the past tense to describe an example otherwise indicated as constructive or prophetic is not intended to reflect that the constructive or prophetic example has actually been carried out.

We claim:

1. A method for the deconvolution of an NMR spectrum of a chemical mixture comprising the steps of:
obtaining a 2D ¹H-¹H TOCSY spectrum of a chemical mixture, the spectrum comprising an N₁×N₂ matrix T with elements (Tₖⱼ);
applying direct covariance processing with regularization to matrix T to determine the covariance matrix C with elements (Cₖⱼ), wherein C=(T^{T}·T)^{1/2}, comprising diagonal peaks and cross-peaks along the two frequency axes of C;
applying standard peak picking to identify the cross-peaks of matrix C, represented by (k,k′), wherein k and k′ denote the position of each cross-peak;
for each cross-peak entry (k,k′), determining a consensus trace q^{(kk′)} by processing the k^{th} and k′^{th} rows according to qⱼ^{(kk′)}=min(Cₖⱼ,C_{k′,j}), wherein index j goes over all N₂ columns;
quantitatively comparing each 1D ¹H consensus trace qⱼ^{(kk′)} with every other consensus trace qⱼ^{(mm′)} via the inner product P_{kk′, mm′} to determine a similarity measure 1−P_{kk′,mm′} between pairs of traces;
clustering the complete set of consensus traces q^{(kk′)} and identification of those traces corresponding to 1D ¹H spectra of individual spin systems; and
identifying unique sets of spin systems as corresponding traces of the covariance matrix to create a final set of magnitude traces.

2. A method according to claim 1, further comprising the step of:
identifying and assigning at least one individual component of the chemical mixture from the final set of TOCSY traces.

3. A method according to claim 2, wherein the final set of TOCSY traces of the individual components are identified and assigned by screening of a spectral database.

4. A method according to claim 1, wherein clustering the complete set of consensus traces q^{(kk′)} is displayed as a dendrogram to identify traces of the covariance matrix corresponding to 1D ¹H spectra of individual spin systems.

5. A method according to claim 1, wherein the operations are performed by a Nuclear Magnetic Resonance System operatively coupled with a means for deconvolution of the 2D ¹H-¹H TOCSY spectrum.

6. A method according to claim 1, wherein the spectrum comprising an N₁×N₂ matrix T represented by the absolute values of its elements is subjected to t₁-noise reduction and thresholding.

7. A method according to claim 6, wherein any matrix T element ki that is smaller than 5 times the average of column i or 3 times the average of row k is set to zero.

8. A method for the deconvolution of an NMR spectrum of a chemical mixture comprising the steps of:
obtaining a 2D ¹³C-¹H HSQC-TOCSY spectrum of a chemical mixture, the spectrum comprising an N₁×N₂ matrix T with elements (Tₖⱼ);
applying indirect covariance processing on the matrix T to determine the covariance matrix C with elements (Cₖⱼ), wherein C=(T·T^{T})^{1/2}, comprising cross-peaks along the two frequency axes of C;
applying standard peak picking to identify the cross-peaks of matrix C, represented by (k,k′), wherein k and k′ denote the position of each cross-peak;
for each cross-peak entry (k,k′), determining a consensus trace q^{(kk′)} by processing the k^{th} and k′^{th} rows according to qⱼ^{(kk′)}=min(Tₖⱼ,T_{k′,j}), wherein index j goes over all N₂ columns;
quantitatively comparing each 1D ¹H consensus trace qⱼ^{(kk′)} with every other consensus trace qᵢ^{(mm′)} via the inner product P_{kk′,mm′} to determine a similarity measure 1−P_{kk′,mm′} between pairs of traces;
clustering the complete set of consensus traces q^{(kk′)} and identification of those traces corresponding to 1D ¹H spectra of individual spin systems; and
identifying unique sets of spin systems and compounds as corresponding traces of the covariance matrix to create a final set of magnitude traces.

9. A method according to claim 8, further comprising the step of:
identifying and assigning at least one individual component of the chemical mixture from the final set of magnitude traces.

10. A method according to claim 9, wherein the final set of magnitude traces of the individual components are identified and assigned by screening of a spectral database.

11. A method according to claim 8, wherein clustering the complete set of consensus traces q^{(kk′)} is displayed as a dendrogram to identify traces of the covariance matrix corresponding to 1D ¹H spectra of individual spin systems.

12. A method according to claim 8, wherein the operations are performed by a Nuclear Magnetic Resonance System operatively coupled with a means for deconvolution of the 2D ¹³C-¹H HSQC-TOCSY spectrum.

13. A method according to claim 8, wherein the spectrum comprising an N₁×N₂ matrix H represented by the absolute values of its elements is subjected to t₁-noise reduction and thresholding.

14. A method according to claim 13, wherein any matrix H element ki that is smaller than 5 times the average of column i or 3 times the average of row k is set to zero.

15. A method according to claim 8, wherein moment filtering is applied along the ¹³C dimension in the triple-rank spectrum R, constructed from the N₁×N₂ matrix H.

16. A method according to claim 8, wherein comparisons involving HSQC planes in R that are void of any signal are reduced by comparing only pairs of planes with ¹H indices (j,j′) that belong to the same spin system.

17. A method for the deconvolution of an NMR spectrum of a chemical mixture comprising the steps of:
obtaining a 2D ¹³C-¹H HSQC spectrum of a chemical mixture, the spectrum comprising an N₁×N₂ matrix H with elements (Hₖᵢ), wherein matrix H has an average value of column i and an average value of row k;
obtaining a 2D ¹³C-¹H HSQC-TOCSY spectrum of a chemical mixture, the spectrum comprising an N₁×N₂ matrix T with elements (Tₖⱼ),
wherein in matrix H and matrix T, N₁ is the number of points along the indirect ¹³C dimension and N₂ is the number of points along the direct ¹H dimension;
constructing a triple rank spectrum R from the elements Hₖᵢ of H and Tₖⱼ of T, wherein Rₖᵢⱼ=HₖᵢTₖⱼ, wherein R corresponds to a collection of 2D ¹³C-¹H HSQC spectra with indices k, i for their ¹³C and ¹H dimensions, respectively, along the additional proton dimension j of the 2D ¹³C-¹H HSQC-TOCSY spectrum;
for each ¹H index pair (j,j′) of R, determining a HSQC consensus plane representing the element-by-element geometric averages according to Qₖᵢ^{(jj′)}=(Rₖᵢⱼ·R_{kij′})^{1/2}, wherein index i goes over all columns and index k goes over all rows;
quantitatively comparing each HSQC consensus plane Qₖᵢ^{(jj′)} with every other consensus plane Qₖᵢ^{(nn′)} via the inner product P_{jj′,nn′} to determine a similarity measure 1−P_{jj′,nn′} between pairs of planes;
clustering the complete set of consensus planes Qₖᵢ^{(jj′)} for the identification of those planes in R corresponding to unique 2D ¹³C-¹H HSQC spectra of individual spin systems; and
identifying unique sets of spin systems with N_{P} protons corresponding to N_{P} HSQC planes in the triple rank spectrum R.

18. A method according to claim 17, further comprising the step of: assigning an individual component corresponding to each unique set of spin systems of the chemical mixture in the triple rank spectrum R.

19. A method according to claim 17, further comprising the steps of:
a) prior to constructing the triple rank spectrum R from the elements H of H and Tₖⱼ of T,
assigning an H matrix element Hₖᵢ a value of 0 if it is less than a first multiple of the average value of column i or less than a second multiple of the average value of row k; and/or
assigning a T matrix element Tₖⱼ a value of 1 if it is a non-zero element; and
b) applying moment filtering along the ¹³C dimension, corresponding to the common index k of matrix H and matrix T, wherein the filtering linewidth was set to a ¹³C linewidth determined by the finite digital resolution along ω₁.

20. A method according to claim 19, wherein the first multiple is from 4 to 6 and the second multiple is from 2 to 4.

21. A method according to claim 17, further comprising the step of: prior to constructing the triple rank spectrum R from the elements Hₖᵢ of H and Tₖⱼ of T, selecting only pairs of HSQC planes in R with ¹H indices (j,j′) that belong to the same spin system for comparison by:
a) comparison of HSQC planes with a 2D ¹H-¹H TOCSY spectrum, or
b) applying indirect covariance processing on the matrix T to determine the covariance matrix C with elements (Cₖⱼ), wherein C=(T^{T}·T)^{1/2}, comprising cross-peaks along the two frequency axes of C, followed by standard peak picking of C to provide a list of ¹H index pairs (j,j′) of R.

22. A method according to claim 17, further comprising the step of: after determining each HSQC consensus plane Qₖᵢ^{(jj′)}, assigning each plane Qₖᵢ^{(jj′)} above the noise a value of 1 and otherwise a value of 0.

23. A method for the deconvolution of an NMR spectrum of a chemical mixture comprising the steps of:
obtaining a 2D ¹³C-¹³C CT (constant time)-TOCSY spectrum of a chemical mixture, the spectrum comprising an N₁×N₂ matrix T with elements (Tₖⱼ);
applying standard peak picking to the 2D ¹³C-¹³C CT-TOCSY spectrum to identify the cross-peaks of matrix T, represented by (k,k′), wherein k and k′ denote the position of each cross-peak along two frequency axes;
for each cross-peak pair (k,k′) and (l,l′) placed symmetrically with respect to the diagonal, extracting the k^{th} and l^{th} row from T to determine a consensus trace qⱼ^{(kl)} according to qⱼ^{(kl)}=min(Tₖⱼ,Tₗⱼ), wherein index j=1, . . . , N₂;
quantitatively comparing each 1D ¹³C consensus trace q^{(kl)} with every other consensus trace q^{(mn)} to determine a similarity measure 1−P_{kl,mn} between pairs of traces; and
clustering the complete set of consensus traces q^{(kl)} and identification of those traces that represent 1D ¹³C spectra of individual spin systems.

24. A method according to any one of claim 1, 8, 21, or 23, wherein the standard peak picking comprises determining local maxima above a threshold.

25. A method according to any one of claim 1, 8, 17, or 23, wherein the chemical mixture comprises material of biological origin.

26. A method according to any one of claim 1, 8, 17, or 23, wherein the chemical mixture comprises material of synthetic origin.

27. A system for the deconvolution of a chemical mixture by covariance spectroscopy comprising a Nuclear Magnetic Resonance System for producing a two-dimensional total correlation spectroscopy spectrum and a means for deconvolution of the two-dimensional total correlation spectroscopy spectrum, wherein the means for deconvolution comprises a computational system operable according to any one of claim 1, 8, 17, or 23.
